(19) United States
(12) Patent Application Publication
(10) Pub. No.: US 2026/0086061 A1
(43) Pub. Date: Mar. 26, 2026

(54) ION SENSING INDUCTORS WITH BIASED DEEP TRENCH

(71) Applicant: Microchip Technology Inc., Chandler, AZ (US)

(72) Inventors: Mazhar Hoque, Gilbert, AZ (US); Amit Rai, Chandler, AZ (US); Samir Fuke, Tempe, AZ (US); Joseph Rascon, Chandler, AZ (US); Arthur B. Eck, Gilbert, AZ (US); Randy Yach, Phoenix, AZ (US)

(73) Assignee: Microchip Technology Inc., Chandler, AZ (US)

(21) Appl. No.: 19/179,169

(22) Filed: Apr. 15, 2025

Related U.S. Application Data
(60) Provisional application No. 63/698,968, filed on Sep. 25, 2024.
(60) Provisional application No. 63/698,973, filed on Sep. 25, 2024.
(60) Provisional application No. 63/698,986, filed on Sep. 25, 2024.
(60) Provisional application No. 63/728,309, filed on Dec. 5, 2024.
(60) Provisional application No. 63/728,295, filed on Dec. 5, 2024.
(60) Provisional application No. 63/728,279, filed on Dec. 5, 2024.

(51) Int. Cl. G01N 27/22; H10D 1/64

(52) U.S. Cl. CPC G01N 27/226; H10D 1/64

(57) ABSTRACT

Inductors and biased deep trench isolation (DTI) varactors may detect the type and concentration of ions in a fluid. An ion sensing device comprises: a deep trench isolation varactor in a substrate having a dielectric and a conductor and biased to create a depletion region in the substrate proximate the deep trench; a sense electrode operable to become electrically charged when interacting with an ionized fluid, wherein the sense electrode is operable to electrically charge the deep trench isolation varactor; an inductor proximate the deep trench isolation varactor and configured so that a change of a characteristic of the deep trench isolation varactor induces a change in the quality factor of the inductor; and a fluid property measurement circuit operable to determine a change in the quality factor of the inductor and output a fluid property signal.

### RELATED PATENT APPLICATIONS

This application claims priority to commonly owned U.S. Provisional Patent Application Nos. 63/698,968; 63/698,973; and 63/698,986, all filed Sep. 25, 2024 and U.S. Provisional Patent Application Nos. 63/728,309; 63/728,295; and 63/728,279, all filed Dec. 5, 2024, the entire contents of which are hereby incorporated by reference for all purposes.

### TECHNICAL FIELD

The present disclosure relates to ion sensing in fluids, in particular, ion sensing in fluid via inductors using biased deep trench isolation.

### BACKGROUND

Ion sensors can detect ion type/concentration of a fluid using ion sensing transistors, inductors, and capacitors. Acid/base balance or pH level (hydrogen ion concentration) in human bodies are critical for proper health. Ion sensors may be used to measure pH of body fluids. Human blood may have a pH in the range of 7.35-7.45. Human saliva may have a pH in the range of 6.2-7.6. Human sweat may have a pH in the range of 4.5 -7.0. Human urine may have a pH in the range of 4.5-8.0. Changes in pH levels of these bodily fluids may indicate medical problems. A drop in pH can be a result of increased bodily production of acid or a loss of bicarbonate. A rise in pH can be caused by a loss of acid due to an increased rate of CO₂ excretion. Variations in pH outside normal range for a long time may cause damage to cells, tissues, and organs.

Ion sensors may also be used to detect virus, bacteria, or early-cancer, and analyze biochemical fluids and perform DNA sequencing. Ion sensors may be used in other applications such as agricultural (crops), industrial (food), mining, and environmental (water pollution).

Ion sensing transistors (ISFET) have previously comprised field effect transistors (FETs) with gate material removed to expose gate oxide directly to the fluid being tested to detect ions. Later, complementary metal oxide semiconductor (CMOS) technology has been used to sense ions in a fluid. A nitride passivation layer in standard CMOS technology acts as a pH/ion sensitive material. The top metal layer in a CMOS technology can be used as a sense electrode, which modulates transistor characteristics based on type/concentration of ions in the fluid in contact with the passivation layer.

A varactor is a type of semiconductor device whose capacitance varies with the applied bias voltage. The variable capacitance of the varactor results from the depletion region in the p-n junction changing its size as the bias voltage changes. Varactors are found in voltage-controlled oscillators (VCOs), LC tank circuits, frequency multipliers, and tunable filters. Varactors using a metal oxide semiconductor field effect transistor (MOSFET) typically have a large footprint on an integrated circuit (IC) because the capacitor area is defined by the transistor gate area.

Inductors on silicon substrates may be used in an integrated circuit (IC). The most common type of inductor is a planar inductor. A planar inductor is a spiral pattern of metal conductors on the surface of the silicon substrate. The inductance of the inductor is determined by the number of turns, the area enclosed by the spiral, and the thickness of the metal layer. Increasing the inductance of the inductor requires increasing the footprint of the inductor on the silicon substrate.

Deep Trench Isolation (DTI) is a semiconductor manufacturing process used to create highly isolated regions within ICs. DTI involves etching deep trenches into the silicon wafer, filling the trench with an insulating material, and then planarizing the surface. DTI allows for the creation of smaller, more densely packed transistors, increasing the number of devices that can be integrated onto a single chip. DTI is used to create high voltage power devices in Bipolar Complementary Metal-Oxide-Semiconductor (CMOS) Double-Diffused Metal-Oxide-Semiconductor (DMOS) (BCD) technology.

There is a need for ion sensing devices in smaller CMOS footprints.

### SUMMARY

Aspects provide a device, comprising: a substrate doped to form a first well; a first deep trench etched in the substrate; a dielectric in the first deep trench; a first conductor within the dielectric in the first deep trench and biased to create a first depletion region in the substrate proximate the first deep trench, wherein the first conductor and first depletion region form a first deep trench isolation varactor; a sense electrode operable to become electrically charged when interacting with an ionized fluid, wherein the sense electrode is operable to electrically charge the first deep trench isolation varactor; an inductor proximate the first deep trench isolation varactor and configured so that a change of a characteristic of the first deep trench isolation varactor induces a change in the quality factor of the inductor; and a fluid property measurement circuit operable to determine a change in the quality factor of the inductor and output a fluid property signal.

According to aspects, there is provided a device as in the preceding paragraph, comprising a sensing membrane connected to the sense electrode and operable to electrically communicate with the sense electrode, wherein the sensing membrane is sensitive to any ion type or a specific ion type in the ionized fluid.

According to aspects, there is provided a device as in one of the preceding two paragraphs, comprising: a second well surrounding the substrate and operable to isolate the substrate; and a buried layer proximate the substrate and operable to isolate the substrate, whereby the isolated substrate is biased.

According to aspects, there is provided a device as in one of the preceding three paragraphs, wherein at least one of a length, a width, or a depth of the trench or at least one of a length, a width, or a depth of the conductor is selected based on a strength of an eddy current induced by the inductor.

According to aspects, there is provided a device as in one of the preceding four paragraphs, comprising: a second deep trench etched in the substrate; a dielectric in the second deep trench; and a second conductor within the dielectric in the second deep trench and biased to create a second depletion region in the substrate proximate the second deep trench, wherein the second conductor and second depletion region form a second deep trench isolation varactor, wherein the sense electrode is operable to electrically charge the second deep trench isolation varactor, wherein the first and second deep trenches are spaced apart so that the first and second depletion regions are separate.

According to aspects, there is provided a device as in one of the preceding five paragraphs, wherein the second deep trench isolation varactor is electrically insulated from the ionized fluid, whereby the second deep trench isolation varactor is a reference varactor, wherein a reference inductor is proximate the reference varactor.

According to aspects, there is provided a device as in one of the preceding six paragraphs, wherein the spacing between the first deep trench and the second deep trench is based on a strength of an eddy current induced by the inductor.

According to aspects, there is provided a device as in one of the preceding seven paragraphs, further comprising: a silicon base; and an insulator on the silicon base, wherein the substrate is on the insulator.

According to aspects, there is provided a device as in one of the preceding eight paragraphs, comprising: a control gate operable to reset or calibrate an electrical communication between the sense electrode and the first deep trench isolation varactor.

Aspects provide a method, comprising: sensing an ionized fluid via a sense electrode; charging a first deep trench isolation varactor via the sense electrode based on the sensing an ionized fluid, wherein the first deep trench isolation varactor comprises a conductor in a dielectric in a deep trench in a substrate, the conductor biased to create a depletion region in the substrate proximate the deep trench; inducing a change in a quality factor of an inductor via charging the first deep trench isolation varactor; measuring a quality factor of the inductor; and outputting a fluid property signal corresponding to the measured quality factor of the inductor.

According to aspects, there is provided a method as in the preceding paragraph, wherein sensing an ionized fluid via a sense electrode comprises sensing a specific ion type.

According to aspects, there is provided a method as in one of the preceding two paragraphs, comprising: measuring a quality factor of a reference inductor; and comparing the measured quality factor of the inductor with the measured quality factor of the reference inductor.

According to aspects, there is provided a method as in one of the preceding three paragraphs, comprising resetting or calibrating the quality factor of the inductor via a control gate.

According to aspects, there is provided a method as in one of the preceding four paragraphs, comprising isolating the first deep trench isolation varactor to form an isolated well and biasing the isolated well to create a depletion region in the isolated substrate proximate the deep trench.

Aspects provide a fluid property sensor made by a process comprising: etching a first deep trench in a substrate, the substrate doped to form a well; filling the first deep trench with a dielectric; placing a first conductor within the dielectric, the conductor biased to create a first depletion region proximate the first deep trench, wherein the first conductor and the first depletion region form a first deep trench isolation varactor; connecting a sense electrode to the first deep trench isolation varactor, wherein the sense electrode is operable to be electrically charged when interacting with an ionized fluid, wherein the sense electrode is operable to electrically charge the first deep trench isolation varactor; positioning an inductor proximate the first deep trench isolation varactor, wherein the inductor has a quality factor; and providing a fluid property measurement circuit operable to determine a change in the quality factor of the inductor and output a fluid property signal.

According to aspects, there is provided a fluid property sensor made by a process as in the preceding paragraph, the process comprising: isolating the substrate using a second well surrounding the substrate; and biasing the isolated substrate.

According to aspects, there is provided a fluid property sensor made by a process as in one of the preceding two paragraphs, wherein at least one of a length, a width, or a depth of the trench or at least one of a length, a width, or a depth of the conductor is selected based on a strength of an eddy current created by the inductor coil.

According to aspects, there is provided a fluid property sensor made by a process as in one of the preceding three paragraphs, the process comprising: etching a second deep trench in the substrate; filling the second deep trench with a dielectric; and placing a second conductor in the dielectric in the second deep trench, the second conductor biased to create a second depletion region, wherein a spacing between the first deep trench and the second deep trench is such that the first depletion region and the second depletion region remain separate.

According to aspects, there is provided a fluid property sensor made by a process as in one of the preceding four paragraphs, comprising forming a reference varactor in the substrate and positioning a reference inductor proximate the reference varactor electrically insulated from the ionized fluid.

According to aspects, there is provided a fluid property sensor made by a process as in one of the preceding five paragraphs, comprising forming a control gate operable to reset or calibrate the first deep trench isolation varactor.

### BRIEF DESCRIPTION OF THE DRAWINGS

A more complete understanding of the disclosure and the advantages thereof may be acquired by referring to the following description, taken in conjunction with the accompanying drawings.

FIGS. 1A, 1B, and 1C illustrate a top view and cross-sectional views, respectively, of a varactor manufactured using DTI in a well.

FIG. 1D shows a cross-sectional, side view of an ion sensor with deep trench isolation varactors through polysilicon inside the deep trench isolation.

FIG. 1E shows a cross-sectional, side view of an ion sensor having a deep trench isolation varactor with a control gate.

FIGS. 2A and 2B illustrate a top view and cross-sectional view, respectively, of a varactor manufactured using DTI in an isolated well.

FIG. 2C shows a cross-sectional, side view of an ion sensor with deep trench isolation varactors through isolated Pwell.

FIG. 2D shows a cross-sectional, side view of an ion sensor with a deep trench isolation varactor similar to that shown in FIG. 2C, wherein the capacitance of the varactor can be compared with a reference varactor not exposed to ionized fluid.

FIGS. 2E and 2F show cross-sectional, side views of ion sensors, both having deep trench isolation varactors similar to that shown in FIG. 2A and having specific sensing membranes sensitive to specific ion types.

FIG. 3 illustrates a method performed for manufacturing an ion sensor having a varactor using deep trench isolation (DTI).

FIG. 4 illustrates a more detailed method performed for manufacturing an ion sensor having a varactor using DTI.

FIGS. 5A, 5B, and 5C illustrate a top view and cross-sectional views, respectively, of an inductor manufactured using DTI, according to examples of the present disclosure.

FIG. 5D shows a cross-sectional, side view of a device for ion sensing with a DTI inductor.

FIG. 5E shows a cross-sectional, side view of a device for ion sensing using a DTI inductor with a control gate.

FIG. 5F shows a cross-sectional, side view of a device for ion sensing using a DTI inductor with a reference DTI inductor.

FIGS. 6A and 6B illustrate a top view and a cross-sectional view, respectively, of an inductor formed of an inductor coil in a trench tied to an inductor coil stacked above the substrate.

FIG. 6C shows a cross-sectional, side view of a device for ion sensing with a DTI inductor tied to metal stack inductor for high quality factor Q.

FIG. 6D shows a cross-sectional, side view of a device for ion sensing with a DTI inductor tied to metal stack inductor for high quality factor Q with a specific sensing membrane.

FIGS. 7A and 7B illustrate a top view and cross-sectional view, respectively, of a vertically stacked high density transformer manufactured using DTI.

FIG. 7C shows a cross-sectional, side view of a device for ion sensing with a DTI inductor and a metal stack inductor and creating a transformer, as shown in FIGS. 7A and 7B.

FIG. 8 illustrates a method performed for manufacturing an ion sensing device having an inductor using DTI.

FIG. 9 illustrates a more detailed method performed for manufacturing an ion sensing device having an inductor using DTI.

FIGS. 10A, 10B, and 10C illustrate a top view and cross-sectional views, respectively, of an inductor manufactured using DTI.

FIG. 10D shows a cross-sectional, side view of a device for ion sensing with a DTI inductor and a layered metal stack arranged in a coil shape, wherein there is a DTI depletion region under the inductor, as shown in FIGS. 10A-10C.

FIG. 10E shows a cross-sectional, side view of a device for ion sensing through substrate by changing inductor quality factor Q with biased polysilicon inside DTI varactors.

FIG. 10F shows a cross-sectional, side view of a device for ion sensing through substrate by changing inductor quality factor Q with biased isolated Pwell with DTI varactors and having a control gate for calibration or reset.

FIG. 10G shows a cross-sectional, side view of a device for ion sensing through substrate by changing inductor quality factor Q with biased polysilicon inside DTI varactors with a specific sensing membrane.

FIG. 10H shows a cross-sectional, side view of a device for ion sensing through an inductor with biased DTI varactors and a reference inductor for comparison

FIGS. 11A and 11B illustrate a top view and cross-sectional view, respectively, of an inductor manufactured using DTI using an isolated well.

FIG. 11C shows a cross-sectional, side view of a device for ion sensing with a DTI inductor wherein the substrate is isolated to allow for biasing of the well (either P-well or N-well) formed by substrate to generate a depletion region under inductor, as shown in FIGS. 11A-11B.

FIG. 12A illustrates a top view and FIGS. 12B, 12C, and 12D illustrate cross-sectional views of the dimensions of a DTI depletion region.

FIG. 13 illustrates a method performed for manufacturing an ion sensing device having an inductor with depletion regions created using DTI.

FIG. 14 illustrates a more detailed method performed for manufacturing an ion sensing device having an inductor with depletion regions created using DTI.

The drawings accompanying and forming part of this specification are included to depict certain aspects of the disclosure. The reference number for any illustrated element that appears in multiple different figures has the same meaning across the multiple figures, and the mention or discussion herein of any illustrated element in the context of any particular figure also applies to each other figure, if any, in which that same illustrated element is shown. The features illustrated in the drawings are not necessarily drawn to scale. It may be noted that the features illustrated in the drawings are not necessarily drawn to scale.

### DESCRIPTION

According to aspects, there is provided ion sensors integrated with CMOS, which may be fabricated with a microcontroller and non-volatile memory on a single chip with additional capabilities. Aspects may use varactors (variable capacitors) created with deep trench isolation (DTI) and biased by inductors as a sensing device to detect the type and concentration of ions in a fluid.

Inductors created with biased deep trench isolation (DTI) varactors underneath may be used as a sensing device to detect the type and concentration of ions in a fluid. Such integrated ion sensing device with CMOS technology may allow them to be smaller, cheaper and portable, so as to be fabricated with microcontroller and non-volatile memory to include additional functionalities.

An inductor built with standard metal stacks that has deep trench isolation varactors underneath consisting of polysilicon/metal inside the trench may be used as a sensing device to detect the type and concentration of ions in a fluid. The polysilicon is connected to a sense electrode, which is usually the top metal right below the nitride passivation layer. When exposed to a fluid with ions, the nitride layer acts as a sensing material and induces charge on the sense electrode. The sense electrode, which is coupled to the polysilicon inside the deep trench may modulate the charge on the polysilicon inside the deep trench. This may alter the depletion regions surrounded by deep trench isolation varactors underneath the stacking inductor causing a change in the effective resistance of the region underneath the stacking inductor. This may affect the eddy current loss in the substrate resulting in a change in the stacking inductor Q (quality factor).

The high resistance depletion regions created by the biased DTI may increase the effective resistance of the area underneath the stacking inductor. This reduces eddy current loss within substrate and results in a higher quality factor Q for the stacking inductor. The depletion region is generated through biasing the poly inside the deep trench.

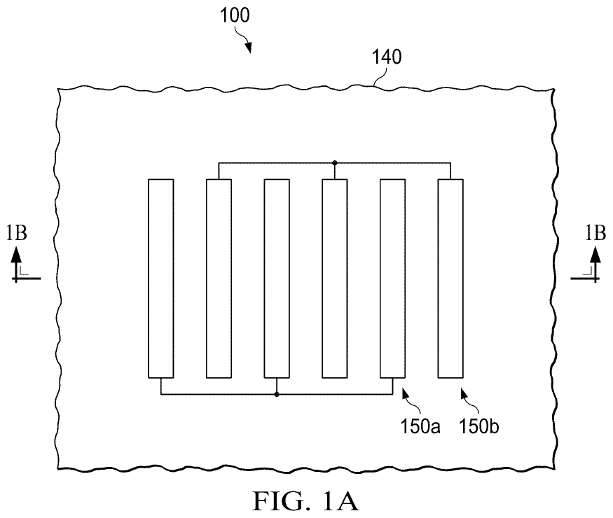

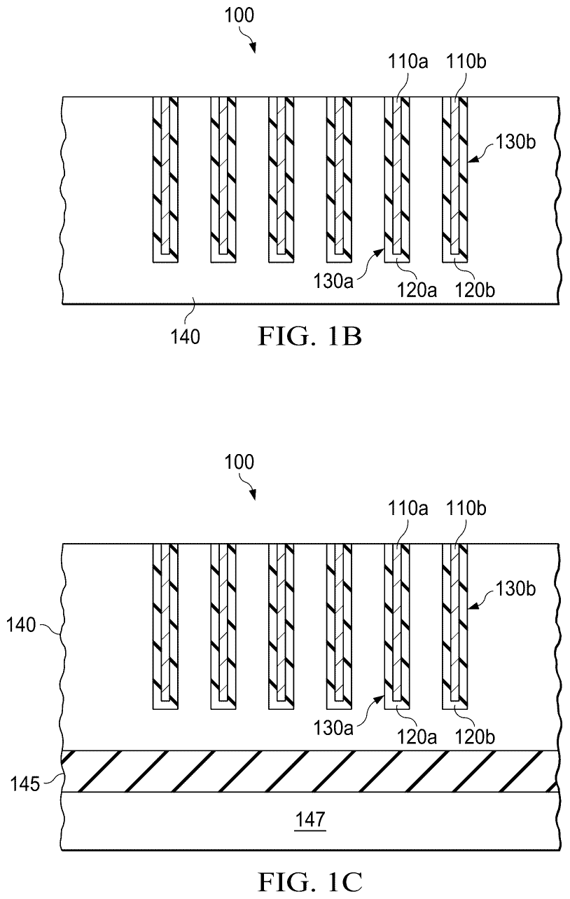

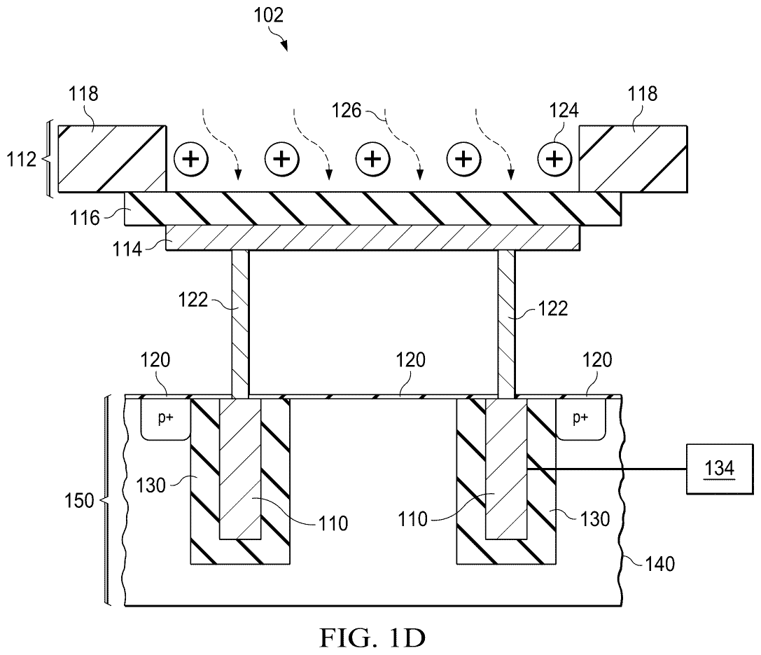

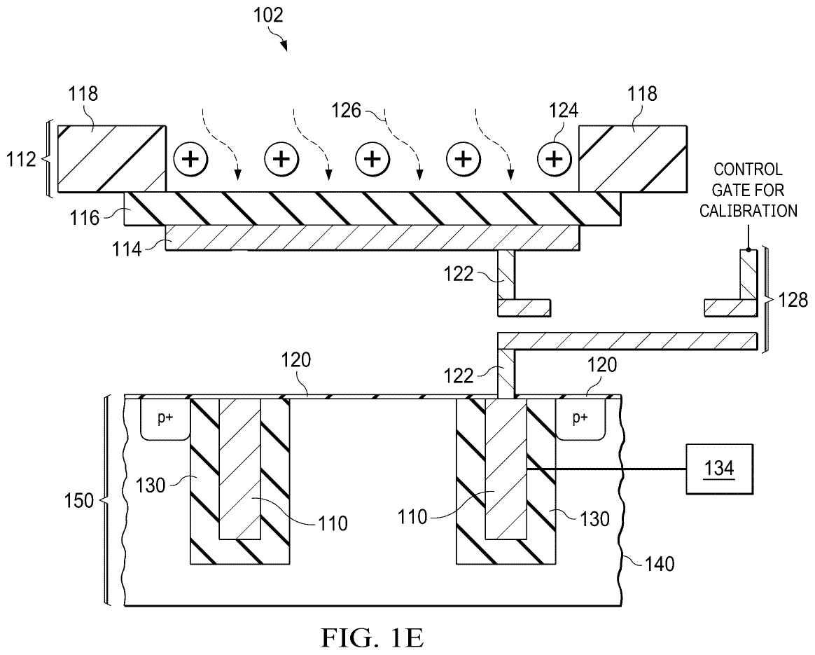

FIGS. 1A, 1B, and 1C illustrate a top view and cross-sectional views, respectively, of a varactor manufactured using DTI in a well. Varactor 100 may be formed with a plurality of varactors formed of conductor 110 and dielectric 120 in trenches 130. For example, trench 130a may be filled with dielectric 120a and conductor 110a. Substrate 140 may act as a bottom electrode and conductor 110a may act as a top electrode such that trench 130a, dielectric 120a, and conductor 110a form varactor 150a. Similarly, trench 130b may be filled with dielectric 120b and conductor 110b. Substrate 140 may act as a bottom electrode and conductor 110b may act as a top electrode such that trench 130b, dielectric 120b, and conductor 110b form varactor 150b.

Conductor 110 may be formed of any suitable conductive material, such as a polysilicon, aluminum, or copper. Dielectric 120 may be formed of any suitable insulating material, such as an oxide (e.g., silicon dioxide) or a nitride (e.g., silicon nitride). Conductor 110 and dielectric 120 may be filled in trench 130 using any suitable technique, such as chemical vapor deposition (CVD) or plasma-enhanced CVD (PECVD).

Trench 130 may have any suitable depth. For example, the depth of trench 130 may be on the order of tens of micro-meters. Trenches 130 may be etched in substrate 140 in parallel. For example, trench 130a may be etched parallel to trench 130b. Trenches 130 may be etched using any suitable technique, such as deep reactive ion etching (DRIE).

Substrate 140 may be doped such that it forms either a P-well or an N-well. Substrate 140 may be any suitable substrate, such as a silicon, silicon on insulator (SOI), gallium arsenide (GaAs), gallium nitride (GaN), silicon carbide (SiC), germanium, indium phosphide (InP), sapphire, or any combination thereof. As shown in FIG. 1C, in some examples, substrate 140 may be layered on insulator 145. Insulator 145 may be formed of any suitable insulating material, such as a buried oxide (e.g., silicon dioxide) or a nitride (e.g., silicon nitride). Insulator 145 may be layered on silicon base 147.

Varactors 150a and 150b may be connected differentially to collectively form varactor 100. The differential connection may improve the quality factor of varactor 100.

The capacitance of varactor 100 may be determined by the surface area of conductor 110. The surface area of conductor 110 may be determined by the depth of trench 130. By increasing the surface area of conductor 110 using the depth of trench 130, the capacitance of varactor 100 may be increased without increasing the footprint of varactor 100 on substrate 140.

FIG. 1D shows a cross-sectional, side view of an ion sensor with deep trench isolation varactors through polysilicon inside the deep trench isolation. The ion sensor 102 comprises a varactor 150 and a sensor 112. The varactor 150 has two trenches 130 in a substrate 140. In this example, the substrate 140 is a P-well. The trenches 130 are filled with a dielectric 120 (e.g., oxide). The respective ones of the trenches 130 also have a conductor 110 in the dielectric 120. The sensor 112 has a sense electrode 114 (e.g., last metal layer), a sensing membrane 116 (e.g., nitride passivation layer), and a sensor protective layer 118 (e.g., a polyimide layer). The sense electrode 114 of the sensor 112 is connected to the conductors 110 of the varactor 150 by one or more vias 122.

Ions 124 in an ionized fluid 126 proximate the sensing membrane 116 change the varactor 150 capacitance and quality factor. The ions 124 in a fluid may modulate the charge on the conductor 110 inside the deep trench 130 through the sensing membrane 116 and the sense electrode 114. This may change the bias across the dielectric 120, which may alter the capacitance of the deep trench varactors 150.

A fluid property measurement circuit 134 measures the charge or a change in the charge on the varactor 150. In some aspects, the fluid property measurement circuit 134 measures the charge or a change in the charge on the conductor 110 of the varactor 150.

FIG. 1E shows a cross-sectional, side view of an ion sensor 102 deep trench isolation varactor 150 with a control gate 128. The sense electrode 114 can be coupled to the conductor 110 (e.g., DTI varactor gate (polysilicon)) through a control gate 128 (e.g., a MOM or MIM capacitor) in a via 122. This may allow another capacitor (MIM/MOM) to be used as a control gate 128. The control gate 128 allows calibration or reset of the capacitance of the DTI varactor 150. The control gate 128 may clear out the stored charges before the ionized fluid is tested.

A fluid property measurement circuit 134 measures the charge or a change in the charge on the varactor 150. In some aspects, the fluid property measurement circuit 134 measures the charge or a change in the charge on the conductor 110 of the varactor 150.

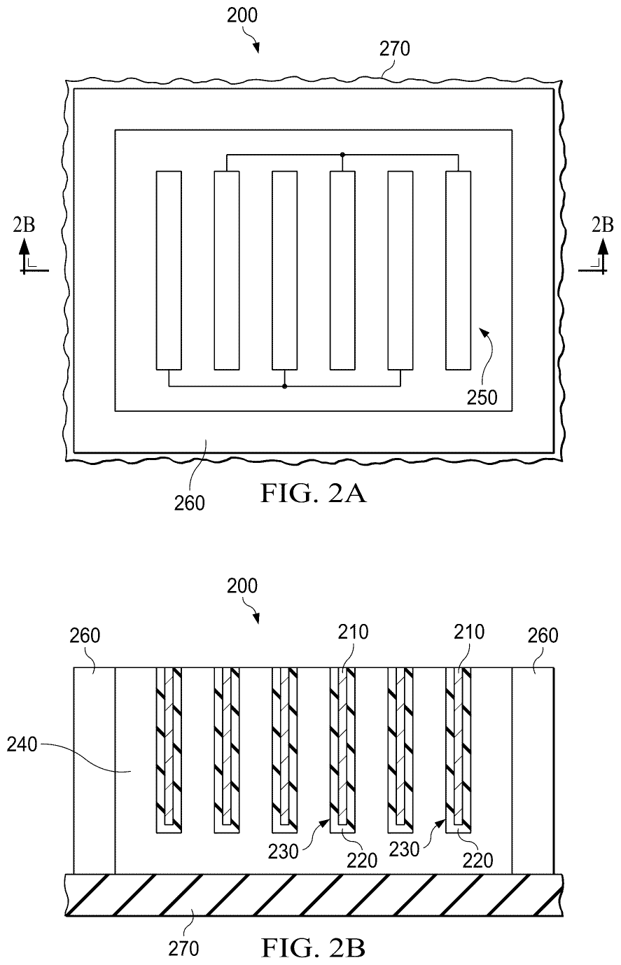

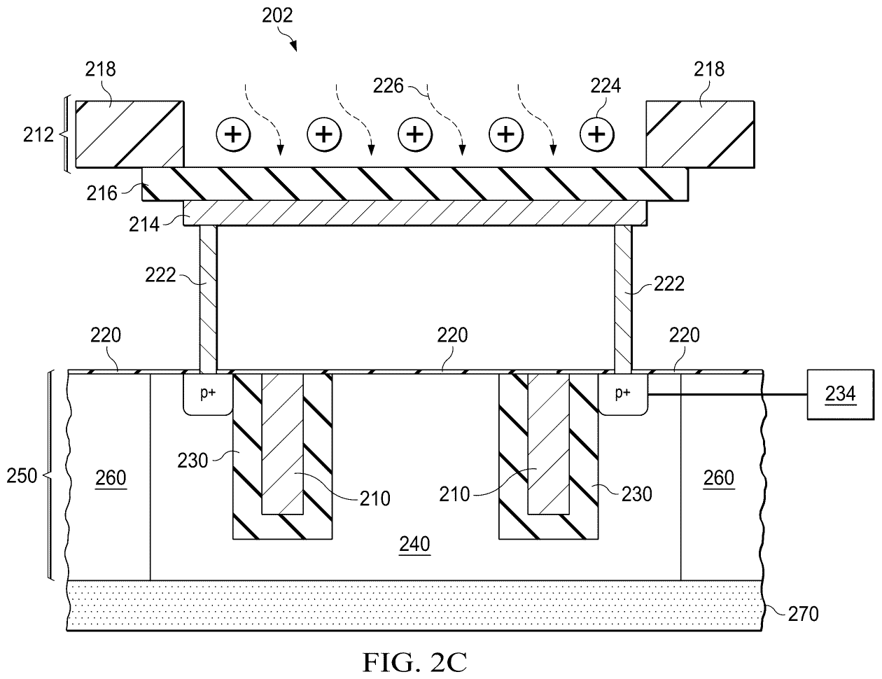

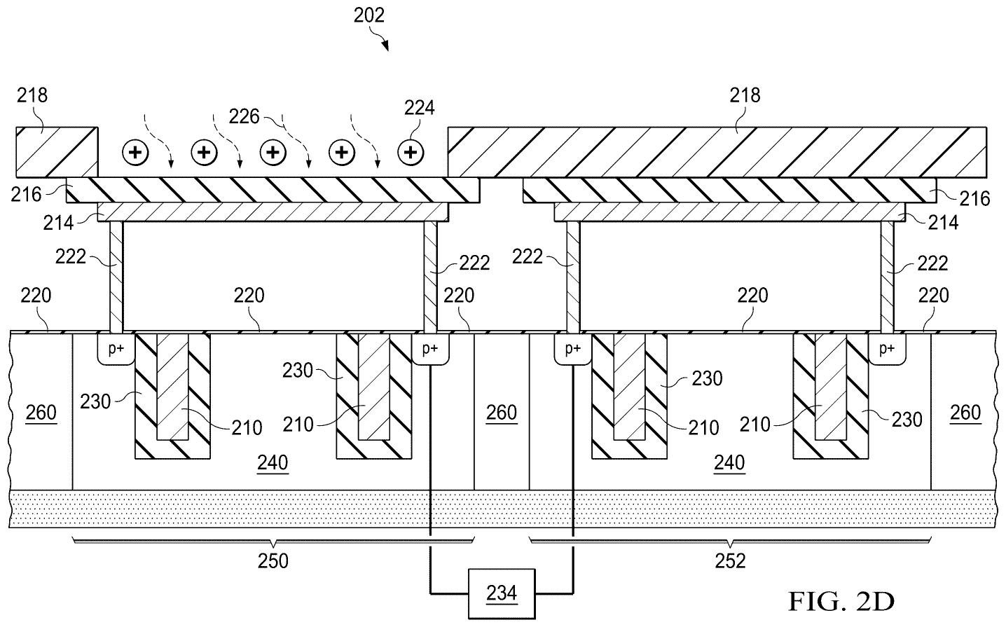

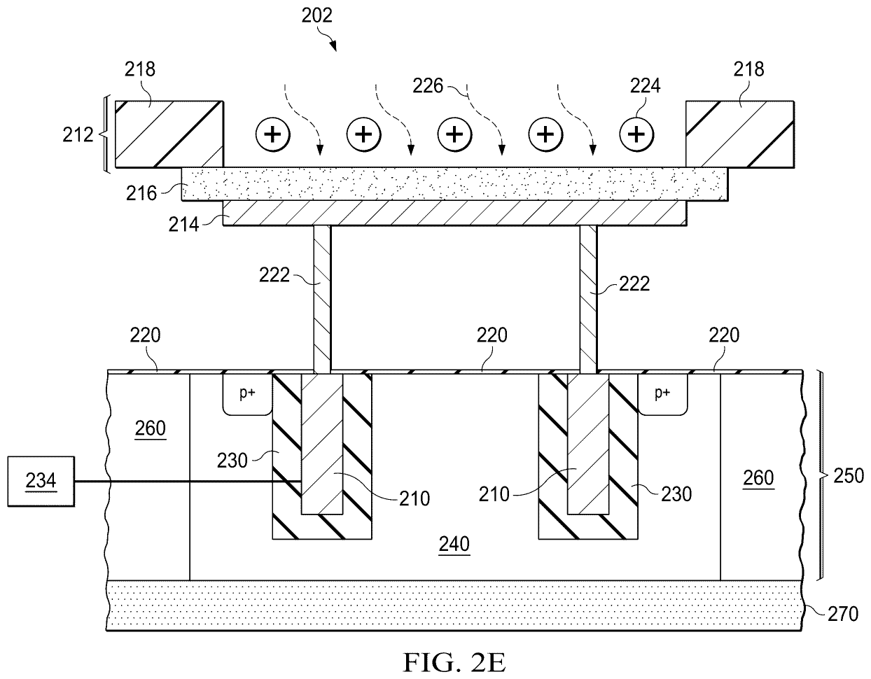

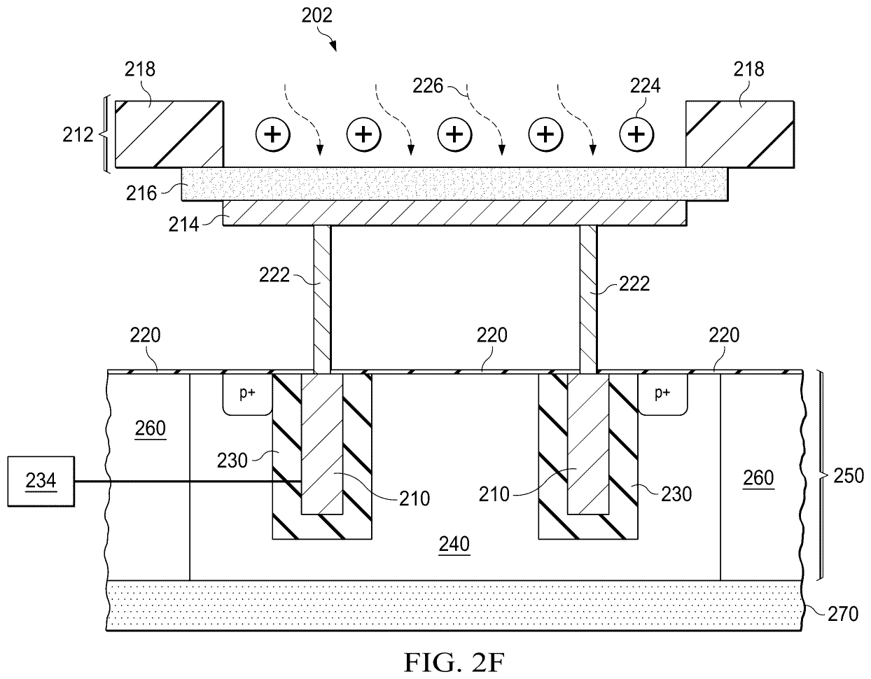

FIGS. 2A and 2B illustrate a top view and cross-sectional view, respectively, of a varactor manufactured using DTI in an isolated well, according to examples of the present disclosure. Varactor 200 may be similar to varactor 100 shown in FIGS. 1A, 1B, and 1C. Similarly, conductor 210, dielectric 220, trench 230, and substrate 240 may be similar to conductor 110, dielectric 120, trench 130, and substrate 140, respectively, shown in FIGS. 1A, 1B, and 1C.

Substrate 240 may be isolated to allow for biasing of the well (either P-well or N-well) formed by substrate 240. Biasing substrate 240 may result in a larger voltage tuning ratio. Substrate 240 may be isolated by surrounding substrate 240 with wells 260 and buried layer 270. Wells 260 and buried layer 270 may have an opposite bias as substrate 240. Specifically, where substrate 240 is a P-well, well 260 may be an N-well and buried layer 270 may be an N-buried layer. Likewise, where substrate 240 is a N-well, well 260 may be a P-well and buried layer 270 may be a P-buried layer.

Varactors 250 may be connected differentially to collectively form varactor 200. The differential connection may improve the quality factor of varactor 200.

FIG. 2C shows a cross-sectional, side view of an ion sensor 202 with deep trench isolation varactors 250 through isolated Pwell. The ion sensor 202 comprises a varactor 250 and a sensor 212. The varactor 250 has two trenches 230 in a substrate 240. In this example, the substrate 240 is a P-well. The Pwell is isolated by wells 260 and buried layer 270. The trenches 230 are filled with a dielectric 220 (e.g., oxide). The respective ones of the trenches 230 also have a conductor 210 in the dielectric 220. The sensor 212 has a sense electrode 214 (e.g., last metal layer), a sensing membrane 216 (e.g., nitride passivation layer), and a sensor protective layer 218 (e.g., a polyimide layer). The sense electrode 214 of the sensor 212 is connected to the substrate 240 of the varactor 250 by one or more vias 222.

The DTI varactor 250 may be created inside an isolated Pwell. The isolated Pwell may be connected to the sense electrode instead of the polysilicon. The ions 224 in an ionized fluid 226 may modulate the charge on the isolated Pwell through the sensing membrane 216 (e.g., nitride passivation layer) and the sense electrode 214 (e.g., last metal plate). This may change the bias across the deep trench dielectric 220 (e.g., oxide), which may alter the capacitance of the deep trench varactors 250.

A fluid property measurement circuit 234 measures the charge or a change in the charge on the varactor 250. In some aspects, the fluid property measurement circuit 234 measures the charge or a change in the charge on the Pwell of the varactor 250.

FIG. 2D shows a cross-sectional, side view of an ion sensor 202 with a deep trench isolation varactor 250 similar to that shown in FIG. 2C. The capacitance of the varactor 250 can be compared with a reference varactor 252 not exposed to ionized fluid. The reference varactor 252 may be electrically insulated from the ionized fluid 226. The sensor protective layer 218 (e.g., polyimide) may prevent the sensing membrane 216 or metal of the reference varactor 252 from interacting with the ions 224 in the ionized fluid 226. Alternatively, there may not be a sensing membrane or a metal plate (sense electrode) associated with or in electrical communication with the reference varactor 252.

A fluid property measurement circuit 234 measures the charge or a change in the charge on the varactor 250 and the reference varactor 252. In some aspects, the fluid property measurement circuit 234 measures the charge or a change in the charge on the Pwells of the varactors 250 and 252.

FIGS. 2E and 2F shows cross-sectional, side views of ion sensors 202, both having deep trench isolation varactors 250 similar to that shown in FIG. 2A, and having specific sensing membranes. The sensing membrane 216 may be a thin layer of material applied to the sense electrode 214. A sensing membrane 216 (e.g., nitride passivation) can be a specific membrane sensitive to a specific ion type. FIG. 2E shows that a material can be chosen for the sensing membrane 216 such that it is selectively sensitive to Calcium (Ca), which will enable detection of Ca ions, without detecting other ions. FIG. 2F shows that a material can be selected for the sensing membrane 216 such that it is selectively sensitive to Potassium (K), which will enable detection of K ions, without detecting other ions. According to aspects, the ion sensing deep trench isolation varactors shown in FIGS. 2E and 2F may be incorporated into the same silicon to allow simultaneous detection of different types of ions in a single fluid via the same silicon.

A fluid property measurement circuit 234 measures the charge or a change in the charge on the varactor 250. In some aspects, the fluid property measurement circuit 234 measures the charge or a change in the charge on the conductor 210 of the varactor 250.

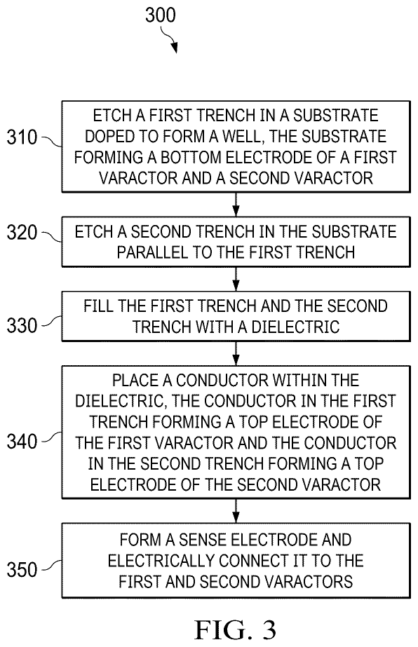

FIG. 3 illustrates a method performed for manufacturing an ion sensing device having a varactor using DTI. Method 300 may be implemented using any suitable semiconductor manufacturing device designed to perform the functions disclosed herein or any other system operable to implement method 300. Although examples have been described above, other variations and examples may be made from this disclosure without departing from the spirit and scope of these disclosed examples.

Method 300 may begin where a first trench may be etched 310 in a substrate doped to form a well. The substrate may form either a P-well or an N-well. The substrate may be any suitable substrate, such as a silicon, silicon on insulator (SOI), gallium arsenide (GaAs), gallium nitride (GaN), silicon carbide (SiC), germanium, indium phosphide (InP), sapphire, or any combination thereof. In some examples, the substrate may be layered on an insulator layered on a silicon base. The substrate may form a bottom electrode of a varactor. The trench may have a depth on the order of tens of micro-meters. The trench may be etched using any suitable technique, such as DRIE.

A second trench may be etched 320 in the substrate parallel to the first trench. The second trench may be similar to the first trench and have a depth on the order of tens of micro-meters and be etched using any suitable technique, such as DRIE.

The first trench and the second trench may be filled 330 with a dielectric. The dielectric may be formed of any suitable insulating material, such as an oxide (e.g., silicon dioxide) or a nitride (e.g., silicon nitride). The dielectric may be filled in the first trench and the second trench using any suitable technique, such as CVD or PECVD.

A conductor may be formed, filled, or placed 340 within the dielectric in the first trench and the second trench. The conductor may be formed of any suitable conductive material, such as a polysilicon, aluminum, or copper. The conductor may be filled 340 in the dielectric in the first trench and the second trench using any suitable technique, such as CVD or PECVD. The conductor in the first trench may form a top electrode of the first varactor and the conductor in the second trench may form a top electrode of the second varactor.

A sense electrode may be formed 350 and electrically connected to the first and second varactors.

Although FIG. 3 discloses a particular number of operations related to method 300, method 300 may be executed with greater or fewer operations than those depicted in FIG. 3. In addition, although FIG. 3 discloses a certain order of operations to be taken with respect to method 300, the operations comprising method 300 may be completed in any suitable order.

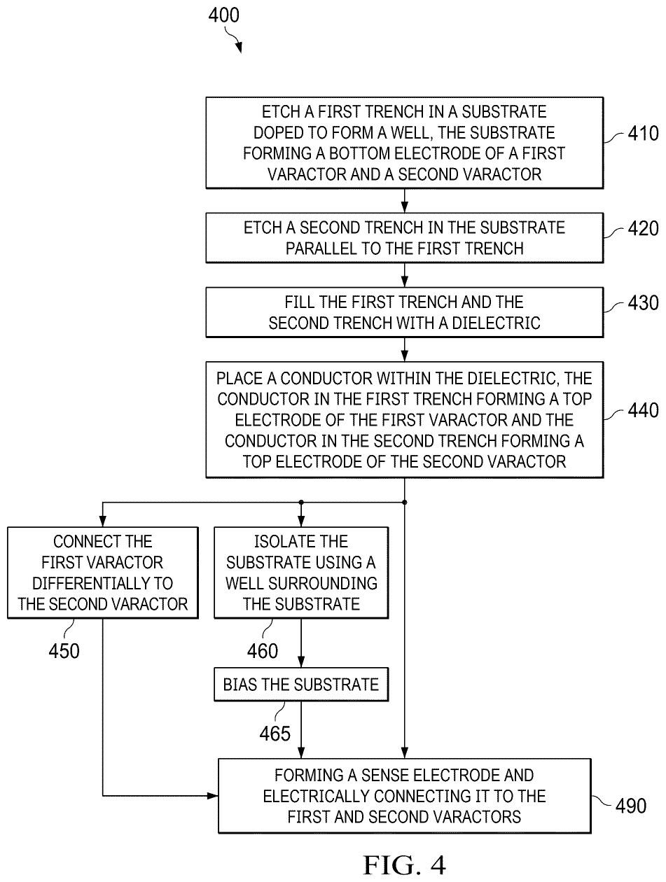

FIG. 4 illustrates a more detailed method performed for manufacturing an ion sensing device having a varactor using DTI. Method 400 may be implemented using any suitable semiconductor manufacturing device designed to perform the functions disclosed herein or any other system operable to implement method 400. Although examples have been described above, other variations and examples may be made from this disclosure without departing from the spirit and scope of these disclosed examples.

Method 400 may begin at block 410 where a first trench may be etched in a substrate doped to form a well. The substrate may form either a P-well or an N-well. The substrate may be any suitable substrate, such as a silicon, silicon on insulator (SOI), gallium arsenide (GaAs), gallium nitride (GaN), silicon carbide (SiC), germanium, indium phosphide (InP), sapphire, or any combination thereof. In some examples, the substrate may be layered on an insulator layered on a silicon base. The substrate may form a bottom electrode of a varactor. The trench may have a depth on the order of tens of micro-meters. The trench may be etched using any suitable technique, such as DRIE.

At block 420, a second trench may be etched in the substrate parallel to the first trench. The second trench may be similar to the first trench and have a depth on the order of tens of micro-meters and be etched using any suitable technique, such as DRIE.

At block 430, the first trench and the second trench may be filled with a dielectric. The dielectric may be formed of any suitable insulating material, such as an oxide (e.g., silicon dioxide) or a nitride (e.g., silicon nitride). The dielectric may be filled in the first trench and the second trench using any suitable technique, such as CVD or PECVD.

At block 440, a conductor may be placed with in the dielectric in the first trench and the second trench. The conductor may be formed of any suitable conductive material, such as a polysilicon, aluminum, or copper. The conductor may be filled in the dielectric in the first trench and the second trench using any suitable technique, such as CVD or PECVD. The conductor in the first trench may form a top electrode of the first varactor and the conductor in the second trench may form a top electrode of the second varactor.

At block 450, the first varactor and the second varactor may be connected differentially. The differential connection of the first varactor and the second varactor may improve the quality factor of the combined varactor.

At block 460, the substrate may be isolated using a well surrounding the substrate. The substrate may be isolated to allow for biasing of the well (either P-well or N-well) formed by the substrate. Biasing the substrate may result in a larger voltage tuning ratio. The substrate may be isolated by surrounding the substrate with wells and a buried layer. Wells and the buried layer may have an opposite bias as the substrate. Specifically, where the substrate is a P-well, the well may be an N-well and the buried layer may be an N-buried layer. Likewise, where the substrate is a N-well, the well may be a P-well and the buried layer may be a P-buried layer.

At block 465, the substrate may be biased. The substrate may be a P-well or an N-well.

A sense electrode may be formed 490 and electrically connected to the first and second varactors. The DTI varactors may be used directly to sense the ions without connecting them differentially (450) or isolating (460) them.

Although FIG. 4 discloses a particular number of operations related to method 400, method 400 may be executed with greater or fewer operations than those depicted in FIG. 4. In addition, although FIG. 4 discloses a certain order of operations to be taken with respect to method 400, the operations comprising method 400 may be completed in any suitable order.

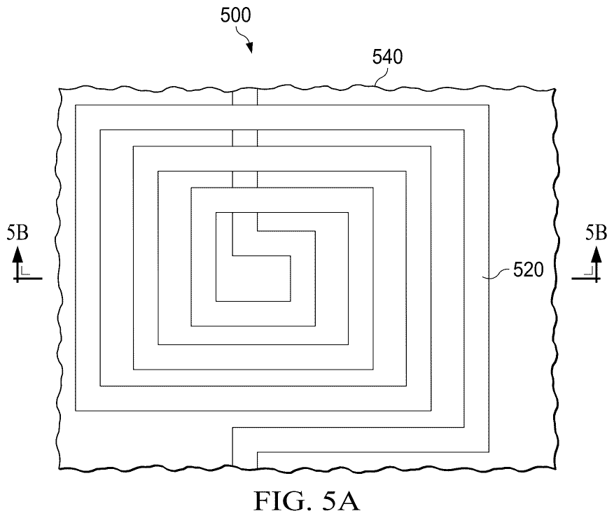

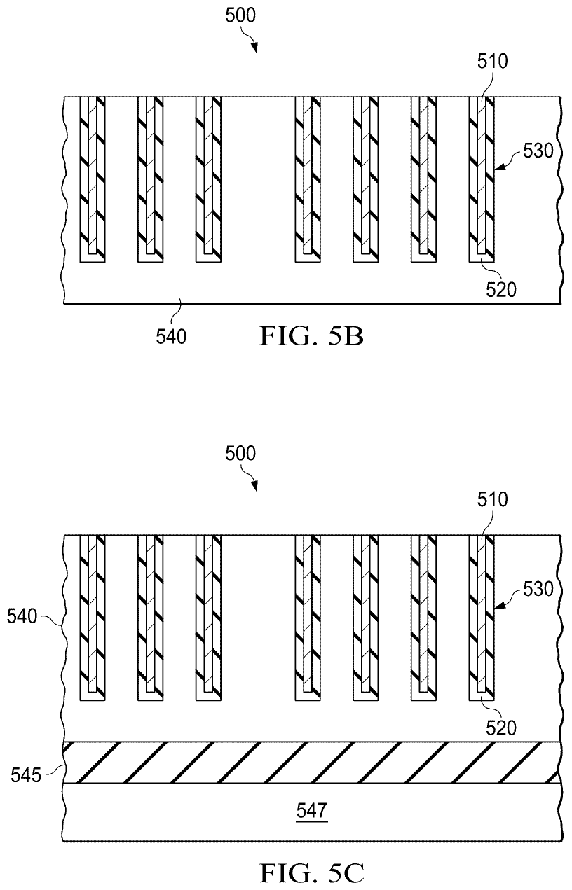

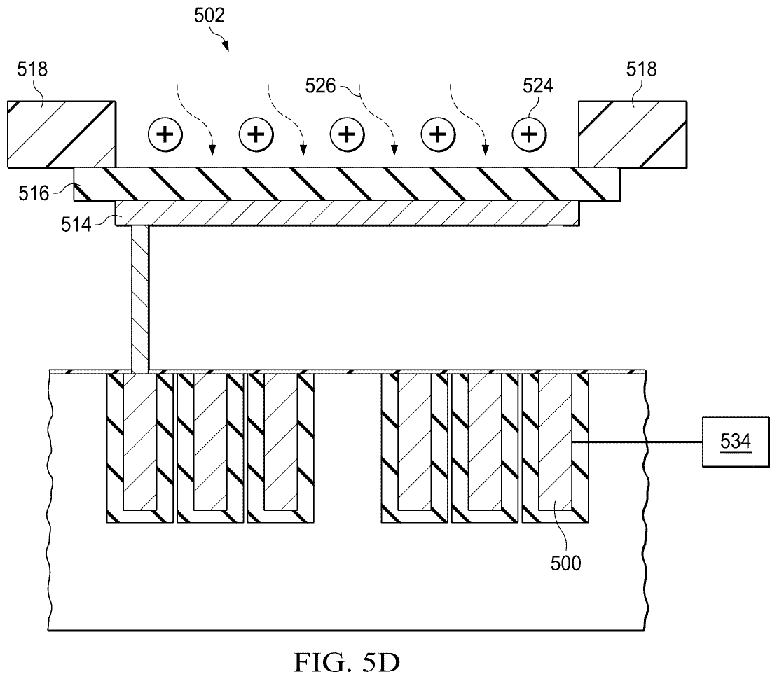

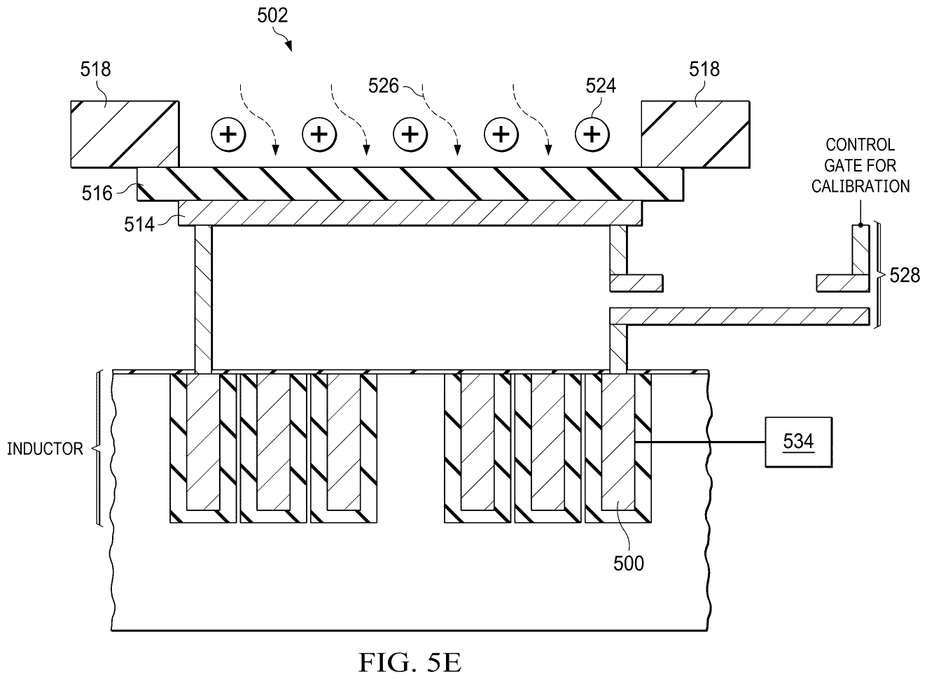

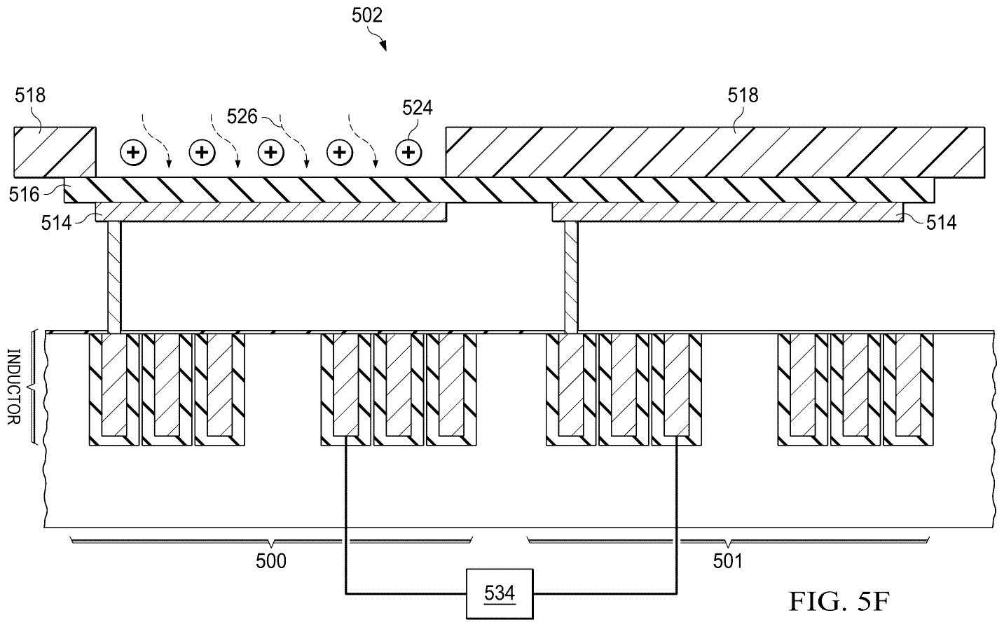

FIGS. 5A, 5B, and 5C illustrate a top view and cross-sectional view, respectively, of an inductor manufactured using DTI, according to examples of the present disclosure. Inductor 500 may be formed of conductor 510 and dielectric 520 in trench 530. Specifically, trench 530 may be etched in a coil pattern and may be filled with dielectric 520 and conductor 510. Conductor 510 and dielectric 520 may be used as inductor track lines to form inductor 500.

Conductor 510 may be formed of any suitable conductive material, such as polysilicon or metal (e.g., aluminum or copper). In some examples, conductor 510 may be replaced with metal inside trench 530. Dielectric 520 may be formed of any suitable insulating material, such as an oxide (e.g., silicon dioxide) or a nitride (e.g., silicon nitride). Conductor 510 and dielectric 520 may be filled in trench 530 using any suitable technique, such as chemical vapor deposition (CVD) or plasma-enhanced CVD (PECVD).

Substrate 540 may be doped such that it forms either a P-well or an N-well. Substrate 540 may be any suitable substrate, such as a silicon, silicon on insulator (SOI), gallium arsenide (GaAs), gallium nitride (GaN), silicon carbide (SiC), germanium, indium phosphide (InP), sapphire, or any combination thereof. As shown in FIG. 5C, in some examples, substrate 540 may be layered on insulator 545. Insulator 545 may be formed of any suitable insulating material, such as a buried oxide (e.g., silicon dioxide) or a nitride (e.g., silicon nitride). Insulator 545 may be layered on silicon base 547.

The inductance of inductor 500 may be determined by the surface area of conductor 510. By increasing the surface area of conductor 510 inside trench 530, the inductor track line resistance may be reduced, which may improve the quality factor of inductor 500.

FIG. 5D shows a cross-sectional, side view of an ion sensor 502 for ion sensing with a deep trench isolation inductor. Ions 524 in an ionized fluid 526 proximate the sensing membrane 516 change the inductance or quality factor of the inductor 500. The ions in a fluid may modulate the field of the inductor created with the polysilicon/metal inside the deep trench through the nitride passivation layer and the metal sense electrode. This may change the inductance and quality factor of the deep trench inductor 500. A fluid property measurement circuit 534 measures the inductance L, quality factor Q or a change of the L or Q of the deep trench inductor 500.

FIG. 5E shows a cross-sectional, side view of an ion sensor 502 for ion sensing using a DTI inductor 500 with a control gate 528. The sense electrode 514 can be coupled to the DTI inductor 500 (for example, polysilicon) through control gate 528 (for example, a MOM or MIM capacitor). This may allow another capacitor (MIM/MOM) to be used as a control gate 528. The control gate 528 may allow calibration or reset of the inductance and quality factor (Q) of the DTI inductor 700. A fluid property measurement circuit 534 measures the inductance L, quality factor Q or a change of the L or Q of the deep trench inductor 500.

FIG. 5F shows a cross-sectional, side view of a device for ion sensing using a DTI inductor 500 with a reference DTI inductor 501. Ion sensing DTI inductor L or Q can be compared with the reference inductor not exposed to fluid. A sensor protective layer 518 (for example, polyimide) prevents the sensing membrane 516 (for example, nitride passivation layer) from interacting with the ions 524 in the ionized fluid 526. A fluid property measurement circuit 534 measures the inductance L, quality factor Q or a change of the L or Q of the deep trench inductor 500 and the reference inductor 501.

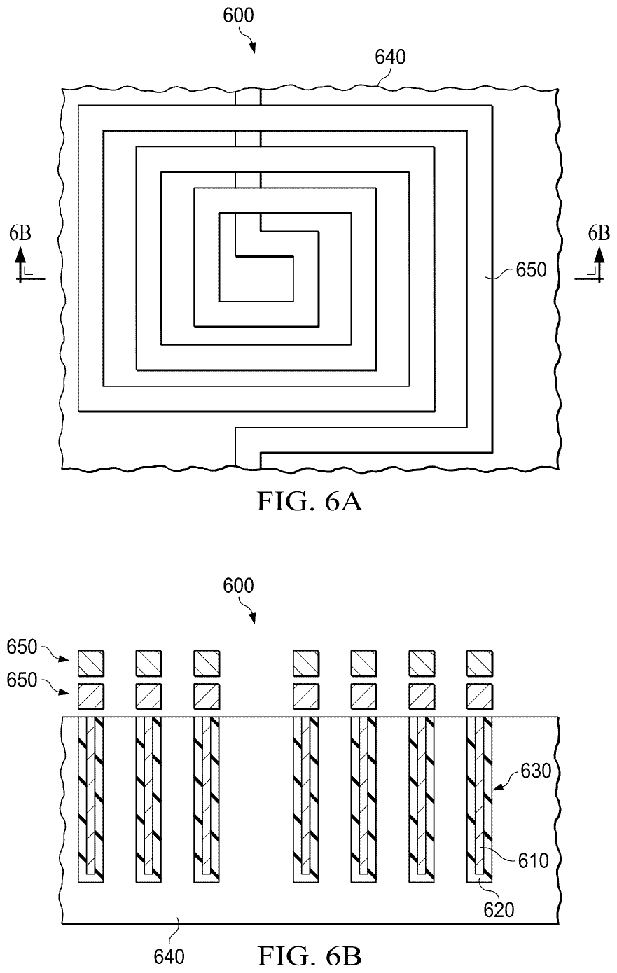

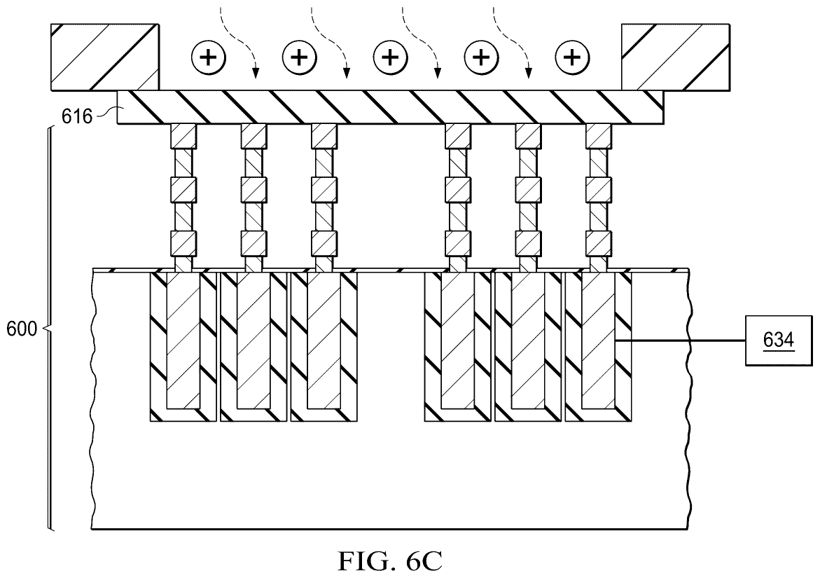

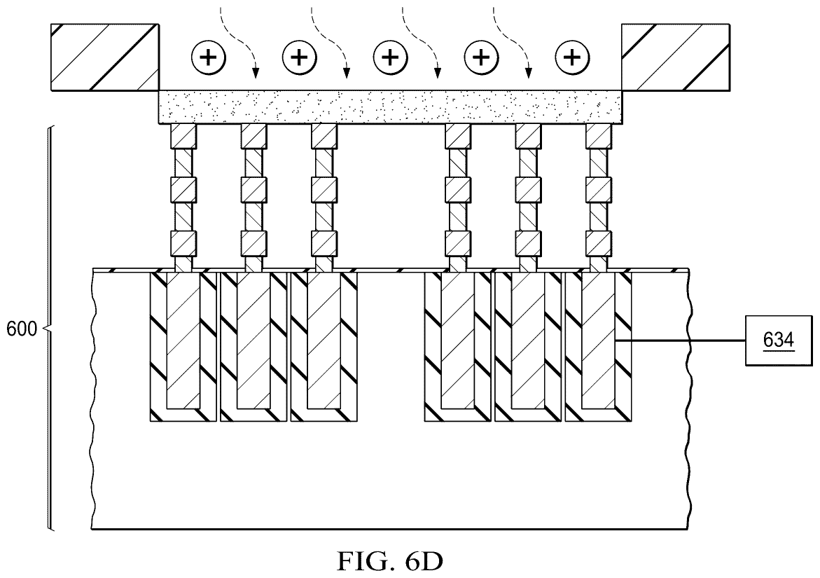

FIGS. 6A and 6B illustrate a top view and cross-sectional view, respectively, of an inductor formed of an inductor coil in a trench tied to an inductor coil stacked above the substrate, according to examples of the present disclosure. Conductor 610, dielectric 620, trench 630, and substrate 640 may be similar to conductor 510, dielectric 520, trench 530, and substrate 540, respectively, shown in FIGS. 5A, 5B, and 5C.

Conductor 610 may be tied to metal stacks 650 in the inter-layer dielectric above substrate 640 to create inductor 600. Tying conductor 610 to metal stacks 650 may reduce track line resistance of inductor 600 and may result in a higher inductor quality factor. Metal stack 650 may be a conventional metal stack used to form an inductor.

FIG. 6C shows a cross-sectional, side view of a device for ion sensing with a DTI inductor tied to stacking inductor for high quality factor Q to create inductor 600. A standard metal stack may be tied to the poly/metal inside the deep trench to create an inductor coil. This may reduce the inductor track line resistance resulting in higher Q (quality factor). A high-Q DTI inductor (polysilicon or metal inside DTI tied to a standard metal stack inside the inter metal layer dielectric) may give higher sensitivity to the ions in the fluid. A fluid property measurement circuit 634 measures the inductance L, quality factor Q or a change of the L or Q of the inductor 600.

FIG. 6D shows a cross-sectional, side view of a device for ion sensing with a DTI inductor tied to stacking inductor for high quality factor Q with a specific sensing membrane. A nitride passivation can be replaced by specific membrane sensitive to a specific ion type. Material X or Y can be chosen such that it is selectively sensitive to Calcium or Potassium, which may enable selective detection of Ca or K ions. This may allow simultaneous detection of different types of ions from the same silicon. A fluid property measurement circuit 634 measures the inductance L, quality factor Q or a change of the L or Q of the inductor 600.

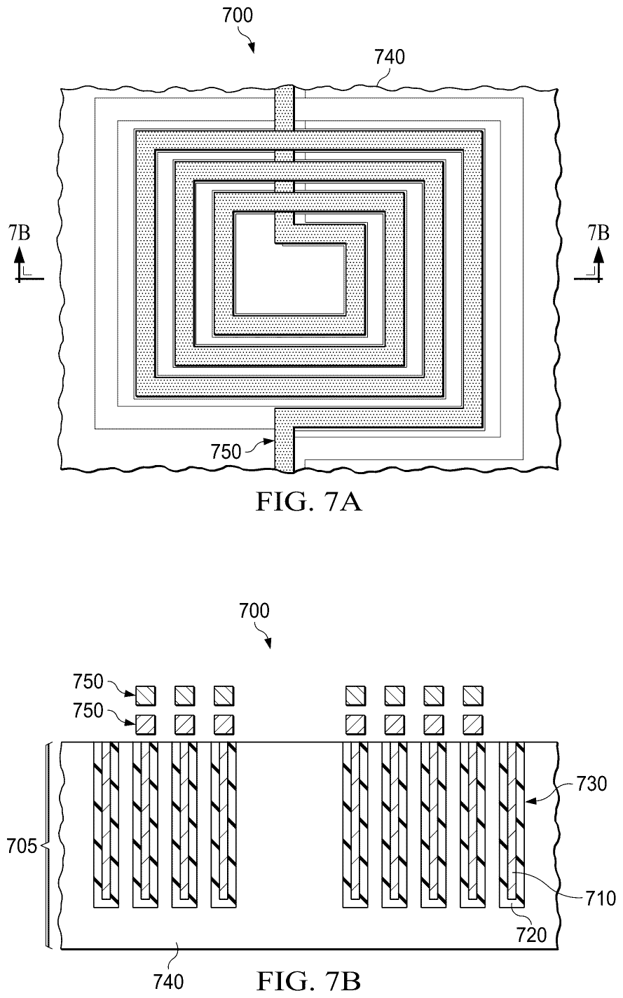

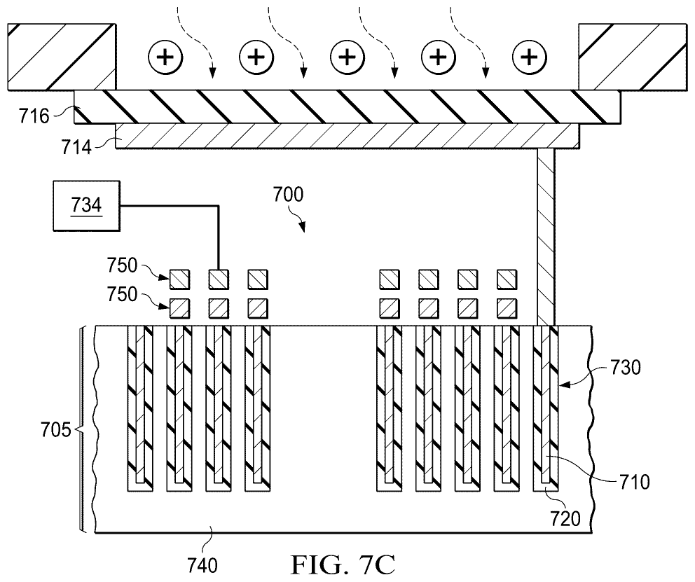

FIGS. 7A and 7B illustrate a top view and cross-sectional view, respectively, of a vertically stacked high density transformer 700 manufactured using DTI, according to examples of the present disclosure. Conductor 710, dielectric 720, trench 730, and substrate 740 may be similar to conductor 510, dielectric 520, trench 530, and substrate 540, respectively, shown in FIGS. 5A, 5B, and 5C. Inductor 705 may be formed of conductor 710 and dielectric 720 in trench 730.

Inductor 705 may be vertically stacked with second inductor 750. Inductor 750 may be a primary coil created with a metal stack above substrate 740 and inductor 705 may be a secondary coil created with conductor 710 and dielectric 720 inside trench 730. Stacking inductor 705 and inductor 750 may create a transformer, such as a Balun or RF transformer, having a smaller footprint on substrate 740.

FIG. 7C shows a cross-sectional, side view of a device for ion sensing with a DTI inductor 750 and a stacking inductor 705 and creating a transformer, as shown in FIGS. 7A and 7B. A fluid property measurement circuit 734 measures the mutual inductance or a change of the mutual inductance of the transformer 700.

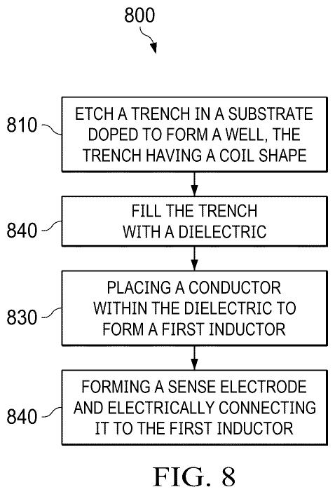

FIG. 8 illustrates a method performed for manufacturing an ion sensing device having an inductor using DTI, according to examples of the present disclosure. Method 800 may be implemented using any suitable semiconductor manufacturing device designed to perform the functions disclosed herein or any other system operable to implement method 800. Although examples have been described above, other variations and examples may be made from this disclosure without departing from the spirit and scope of these disclosed examples.

Method 800 may begin at block 810 where a trench may be etched in a substrate doped to form a well. The substrate may form either a P-well or an N-well. The substrate may be any suitable substrate, such as a silicon, silicon on insulator (SOI), gallium arsenide (GaAs), gallium nitride (GaN), silicon carbide (SiC), germanium, indium phosphide (InP), sapphire, or any combination thereof. In some examples, the substrate may be layered on an insulator layered on a silicon base. The trench may have a depth on the order of tens of micro-meters. The trench may be etched using any suitable technique, such as DRIE, and may have a coil shape.

At block 820, the trench may be filled with a dielectric. The dielectric may be formed of any suitable insulating material, such as an oxide (e.g., silicon dioxide) or a nitride (e.g., silicon nitride). The dielectric may be filled in the trench using any suitable technique, such as CVD or PECVD.

At block 830, a conductor may be placed with in the dielectric in the trench. The conductor may be formed of any suitable conductive material, such as polysilicon or metal (e.g., aluminum or copper). The conductor may be filled in the dielectric in the trench using any suitable technique, such as CVD or PECVD. The conductor in the trench may form a first inductor.

A sense electrode may be formed 840 and electrically connected to the first inductor.

Although FIG. 8 discloses a particular number of operations related to method 800, method 800 may be executed with greater or fewer operations than those depicted in FIG. 8. In addition, although FIG. 8 discloses a certain order of operations to be taken with respect to method 800, the operations comprising method 800 may be completed in any suitable order.

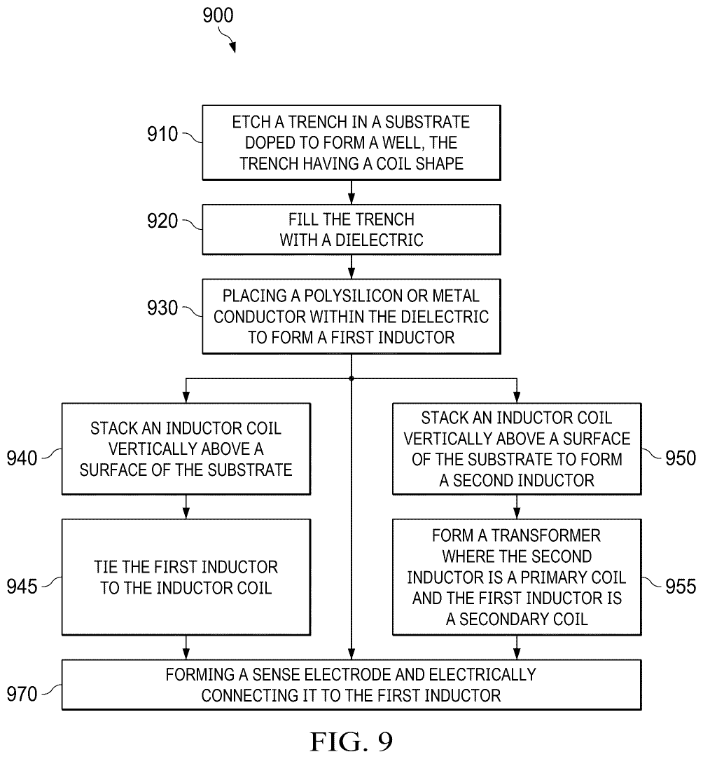

FIG. 9 illustrates a more detailed method performed for manufacturing an ion sensing device having an inductor using DTI, according to examples of the present disclosure. Method 900 may be implemented using any suitable semiconductor manufacturing device designed to perform the functions disclosed herein or any other system operable to implement method 900. Although examples have been described above, other variations and examples may be made from this disclosure without departing from the spirit and scope of these disclosed examples.

Method 900 may begin where a trench may be etched 910 in a substrate doped to form a well. The substrate may form either a P-well or an N-well. The substrate may be any suitable substrate, such as a silicon, silicon on insulator (SOI), gallium arsenide (GaAs), gallium nitride (GaN), silicon carbide (SiC), germanium, indium phosphide (InP), sapphire, or any combination thereof. In some examples, the substrate may be layered on an insulator layered on a silicon base. The trench may have a depth on the order of tens of micro-meters. The trench may be etched using any suitable technique, such as DRIE, and may have a coil shape.

The trench may be filled 920 with a dielectric. The dielectric may be formed of any suitable insulating material, such as an oxide (e.g., silicon dioxide) or a nitride (e.g., silicon nitride). The dielectric may be filled in the trench using any suitable technique, such as CVD or PECVD.

A conductor may be placed 930 with in the dielectric in the trench. The conductor may be formed of any suitable conductive material, such as polysilicon or metal (e.g., aluminum or copper). The conductor may be filled in the dielectric in the trench using any suitable technique, such as CVD or PECVD. The conductor in the trench may form a first inductor.

An inductor coil may be stacked 940 vertically above a surface of the substrate. The first inductor and the inductor coil may be tied 945 together. The first inductor and the inductor coil may form a single inductor. The combined inductor may reduce the track line resistance of the combined inductor and result in a higher inductor quality factor.

An inductor coil may be stacked 950 vertically above a surface of the substrate. The inductor coil may form a second inductor.

A transformer, such as a Balun or RF transformer, may be formed 955 where the second inductor is a primary coil and the first inductor is a secondary coil of the transformer. The transformer may have a smaller footprint on the substrate than a traditional transformer.

A sense electrode may be formed 970 and electrically connected to the first inductor.

Although FIG. 9 discloses a particular number of operations related to method 900, method 900 may be executed with greater or fewer operations than those depicted in FIG. 9. In addition, although FIG. 9 discloses a certain order of operations to be taken with respect to method 900, the operations comprising method 900 may be completed in any suitable order.

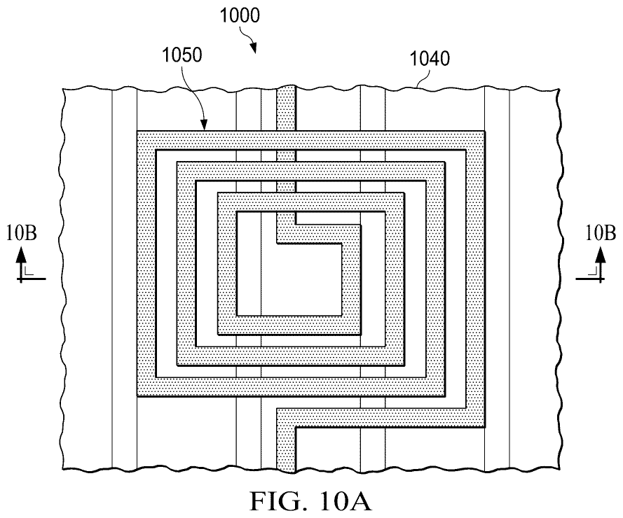

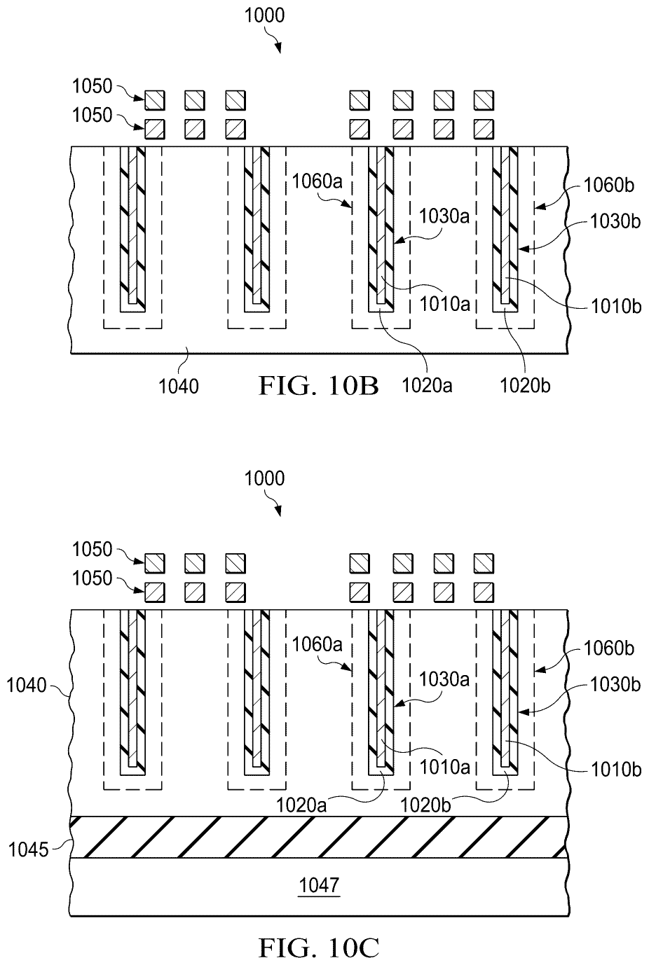

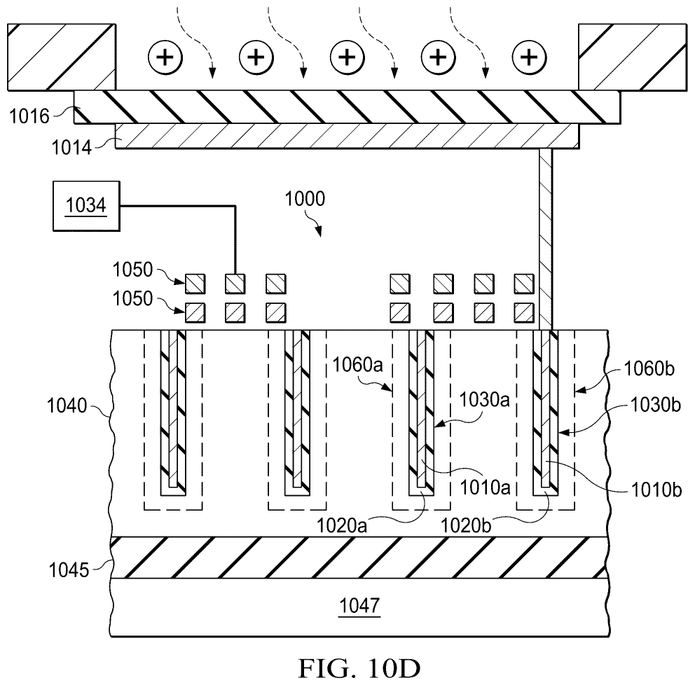

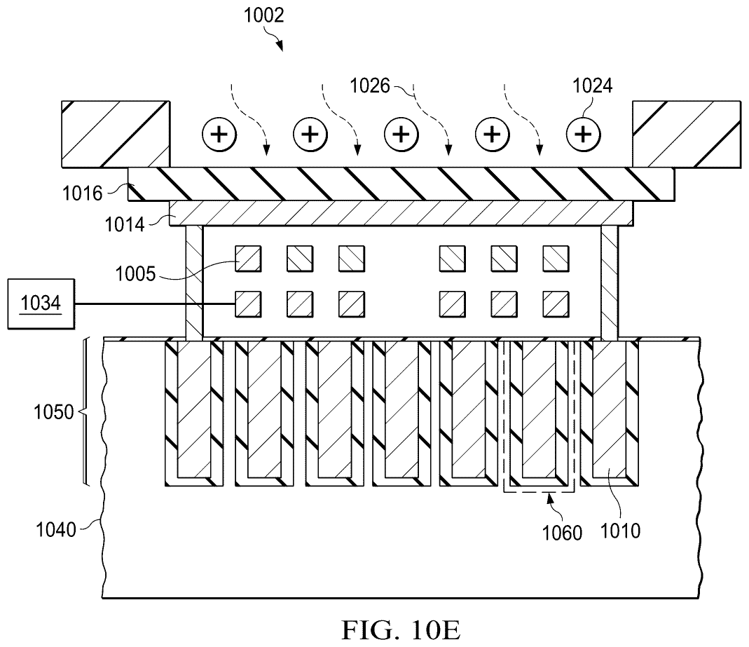

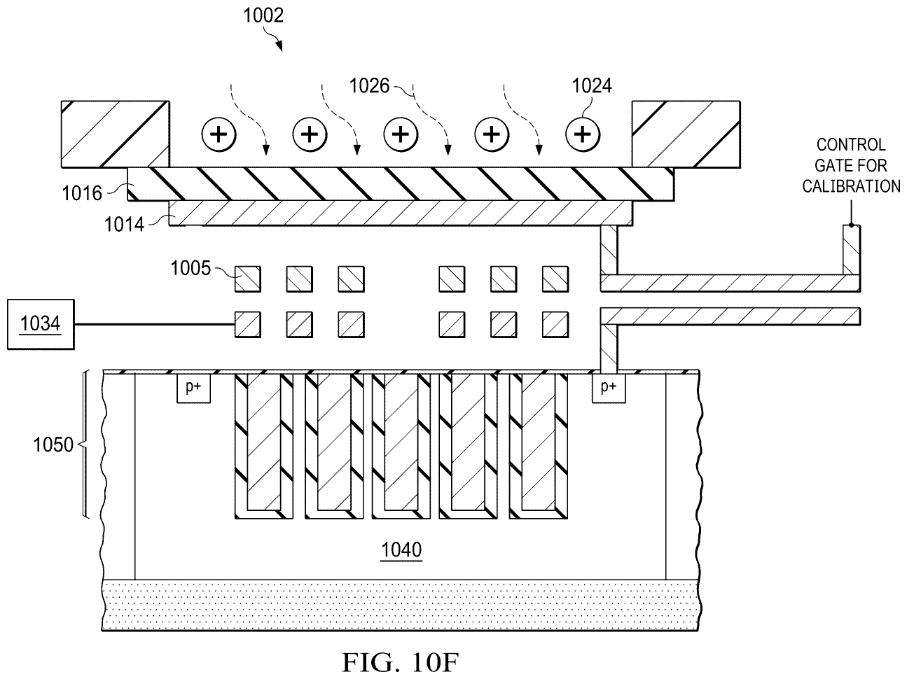

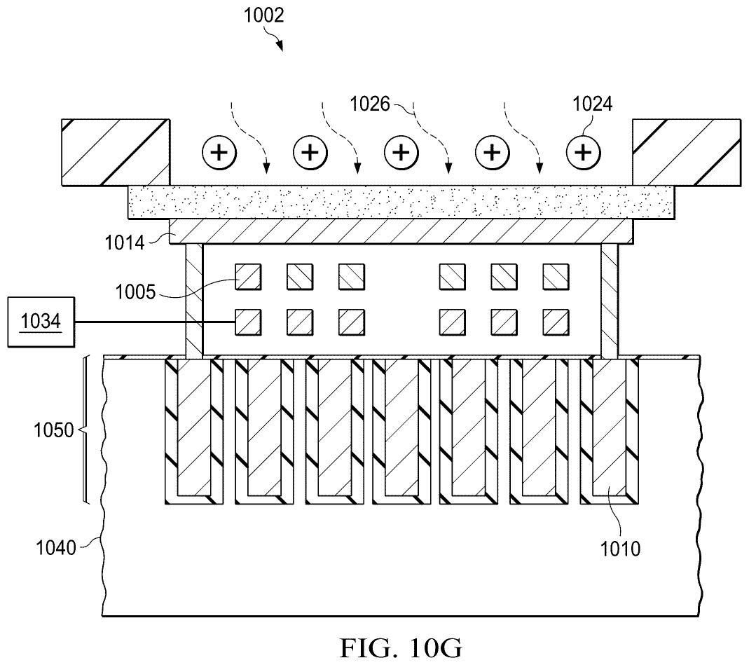

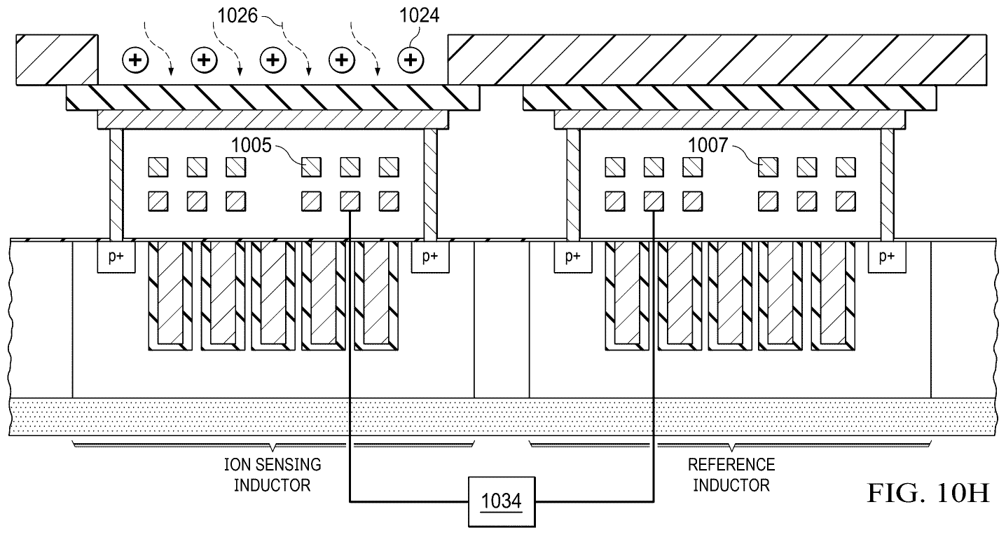

FIGS. 10A, 10B, and 10C illustrate a top view and cross-sectional views, respectively, of an inductor manufactured using DTI. Inductor 1050 may be formed of layered metal stacks arranged in a coil shape. Inductor 1050 may be formed above the surface of substrate 1040. Under inductor 1050 is DTI depletion region 1060. DTI depletion region 1060 may include a plurality of trenches 1030 etched in substrate 1040. Trenches 1030 may be filled with conductor 1010 and dielectric 1020. A given trench 1030, along with conductor 1010 and dielectric 1020, inductor with DTI depletion region 1000 may create DTI depletion region 1060. Trenches 1030 may be spaced such that DTI depletion regions 1060 created by trenches 1030 are as close together as possible without merging. For example, trench 1030a may be spaced from trench 1030b such that DTI depletion region 1060a and DTI depletion region 1060b do not merge.

Conductor 1010 may be formed of any suitable conductive material, such as polysilicon or metal (e.g., aluminum or copper). In some examples, conductor 1010 may be replaced with metal inside trench 1030. Dielectric 1020 may be formed of any suitable insulating material, such as an oxide (e.g., silicon dioxide) or a nitride (e.g., silicon nitride). Conductor 1010 and dielectric 1020 may be filled in trench 1030 using any suitable technique, such as chemical vapor deposition (CVD) or plasma-enhanced CVD (PECVD).

Conductor 1010 may be biased to deplete p-type carriers (when substrate 1040 is a p-well) or n-type carriers (when substrate 1040 is an n-well) and increase the effective resistance under inductor 1050. Biasing conductor 1010 may increase the effective resistance of the area of substrate 1040 under inductor 1050, resulting in a reduction of eddy current loss because the DTI depletion regions 1060 have high resistance. The use of the DTI depletion regions may result in inductor 1050 having a higher quality factor.

Substrate 1040 may be doped such that it forms either a P-well or an N-well. Substrate 1040 may be any suitable substrate, such as a silicon, silicon on insulator (SOI), gallium arsenide (GaAs), gallium nitride (GaN), silicon carbide (SiC), germanium, indium phosphide (InP), sapphire, or any combination thereof. As shown in FIG. 10C, in some examples, substrate 1040 may be layered on insulator 1045. Insulator 1045 may be formed of any suitable insulating material, such as a buried oxide (e.g., silicon dioxide) or a nitride (e.g., silicon nitride). Insulator 1045 may be layered on silicon base 1047.

FIG. 10D shows a cross-sectional, side view of a device for ion sensing with a DTI inductor 1050 formed of layered metal stacks arranged in a coil shape. Inductor 1050 may be formed above the surface of substrate 1040. Under inductor 1050 is DTI depletion region 1000, as shown in FIGS. 10A-10C. A fluid property measurement circuit 1034 measures the quality factor Q or a change of the Q of the inductor 1050.

FIG. 10E shows a cross-sectional, side view of an ion sensor 1002 for ion sensing through a substrate 1040 by changing a quality factor Q of a stacking inductor 1005 with biased conductors 1010 (for example, polysilicon) inside deep trench isolation (DTI) varactors 1050. The ions 1024 in an ionized fluid 1026 may modulate the charge on the conductor 1010 inside the deep trench varactors 1050 through the sensing membrane 1016 (for example, nitride passivation layer) and the sense electrode 1014. This will alter the depletion regions 1060 surrounding deep trench varactors 1050 under the stacking inductor 1005 causing a change in the resistance of the substrate region under the stacking inductor 1005. This may affect or modulate the eddy current loss in the substrate resulting in a change in the inductor Q (quality factor) of the stacking inductor 1005. A fluid property measurement circuit 1034 measures the quality factor Q or a change of the Q of the stacking inductor 1005.

FIG. 10F shows a cross-sectional, side view of a device for ion sensing through substrate by changing inductor Q with biased isolated Pwell with DTI varactors with a control gate for calibration or reset. The sense electrode can be coupled to the isolated Pwell through a MOM or MIM capacitor. This may allow another capacitor (MIM/MOM) to be used as a control gate. The control gate may allow calibration or reset of the inductor Q (quality factor). A fluid property measurement circuit 1034 measures the quality factor Q or a change of the Q of the stacking inductor 1005.

FIG. 10G shows a cross-sectional, side view of a device for ion sensing through substrate by changing inductor Q with biased polysilicon inside DTI varactors with specific sensing membrane. A nitride passivation layer can be replaced by specific membrane sensitive to a specific ion type. Material X or Y can be chosen such that it is selectively sensitive to Calcium or Potassium, which will enable selective detection of Ca or K ions. This may allow simultaneous detection of different types of ions from the same silicon. A fluid property measurement circuit 1034 measures the quality factor Q or a change of the Q of the stacking inductor 1005.

FIG. 10H shows a cross-sectional, side view of a device for ion sensing inductor with biased deep trench varactors and a reference inductor for comparison. The ion sensing inductor with biased deep trench varactors can be compared with a reference inductor not exposed to fluid. Polyimide may prevent the sensing membrane/metal from interacting with the ions in the fluid. A fluid property measurement circuit 1034 measures the quality factor Q or a change of the Q of the stacking inductor 1005 and the reference stacking inductor 1007.

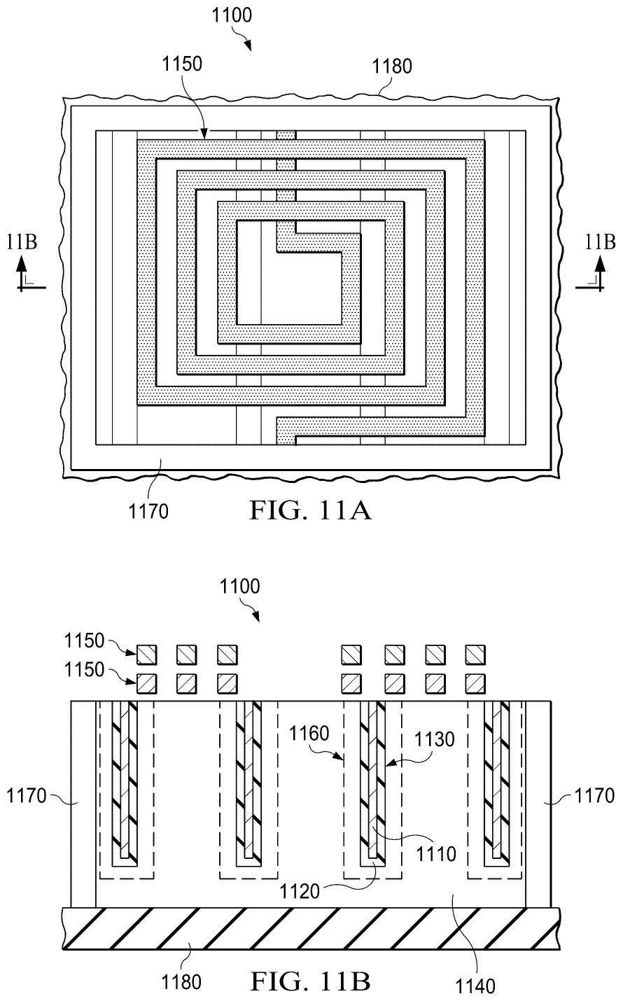

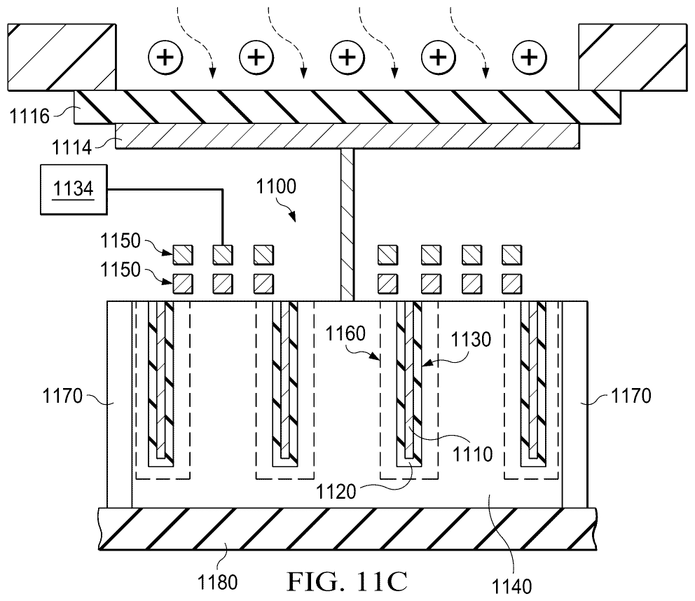

FIGS. 11A and 11B illustrate a top view and cross-sectional view, respectively, of an inductor manufactured using DTI using an isolated well, according to examples of the present disclosure. Conductor 1110, dielectric 1120, trench 1130, substrate 1140, and inductor 1150 may be similar to conductor 1010, dielectric 1020, trench 1030, substrate 1040, and inductor 1050, respectively, shown in FIGS. 10A, 10B, and 10C.

Substrate 1140 may be isolated to allow for biasing of the well (either P-well or N-well) formed by substrate 1140. Biasing substrate 1140 may result in generation of a depletion region under inductor 1150. Biasing conductor 1110, substrate 1140, or both may increase the effective resistance of the area of substrate 1140 under inductor 1150, resulting in a reduction of eddy current loss because the DTI depletion regions 1160 have high resistance. The use of DTI depletion regions 1160 may result in inductor 1150 having a higher quality factor. Substrate 1140 may be isolated by surrounding substrate 1140 with wells 1170 and buried layer 1180. Wells 1170 and buried layer 1180 may have an opposite bias as substrate 1140. Specifically, where substrate 1140 is a P-well, well 1170 may be an N-well and buried layer 1180 may be an N-buried layer. Likewise, where substrate 1140 is an N-well, well 1170 may be a P-well and buried layer 1180 may be a P-buried layer. Isolation of substrate 1140 may be used to protect high sensitivity devices from other interferences caused by other devices within the substrate.

FIG. 11C shows a cross-sectional, side view of a device for ion sensing with a DTI inductor wherein the substrate 1140 is isolated to allow for biasing of the well (either P-well or N-well) formed by substrate 1140. Biasing substrate 1140 may result in generation of a depletion region under inductor 1150, as shown in FIGS. 11A-11B. A fluid property measurement circuit 1134 measures the quality factor Q or a change of the Q of the inductor 1150.

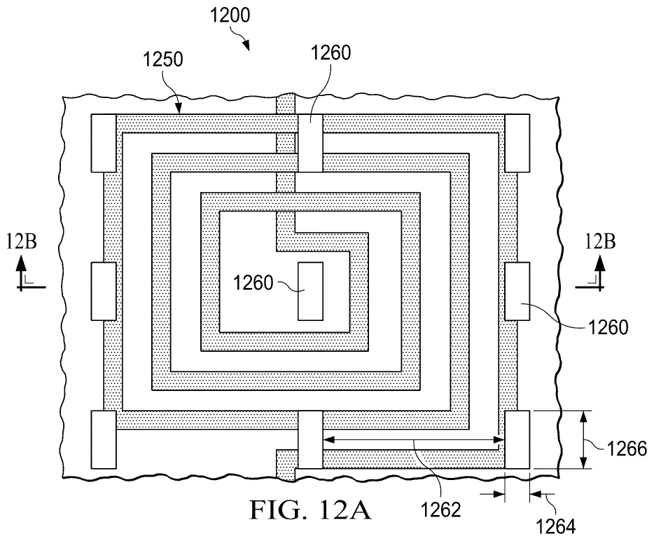

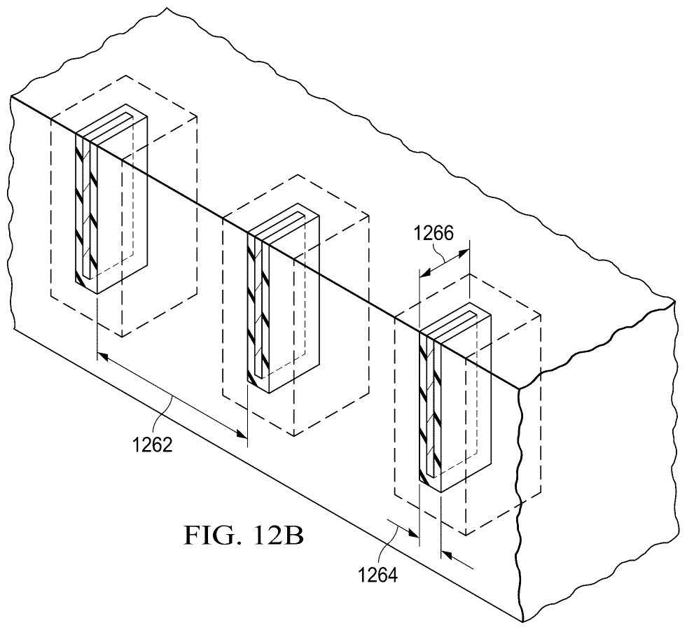

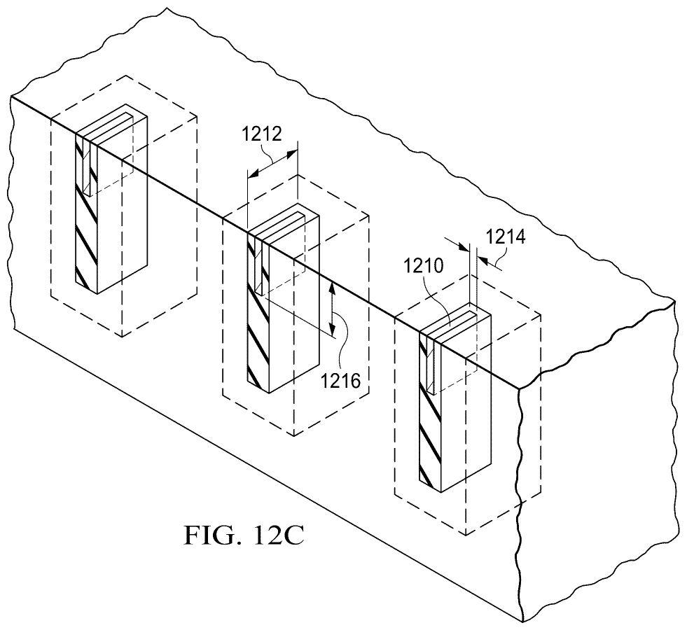

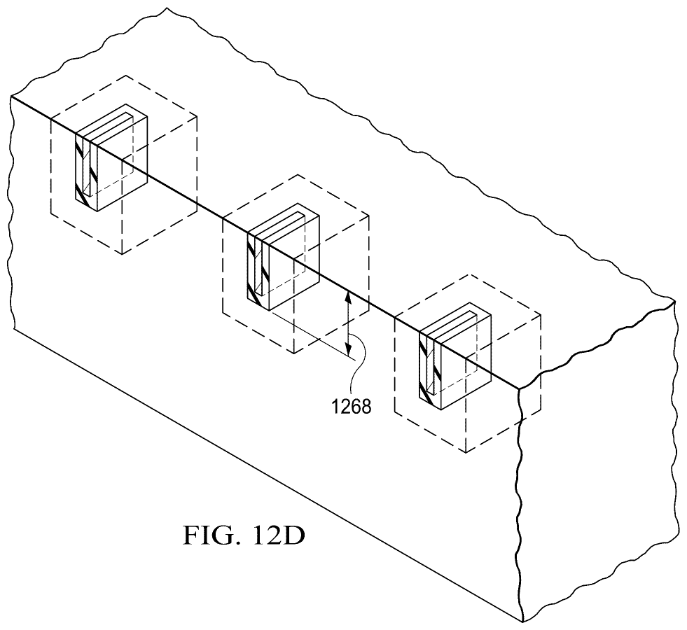

FIG. 12A illustrates a top view and FIGS. 12B, 12C, and 12D illustrate cross-sectional views of the dimensions of a DTI depletion region, according to examples of the present disclosure. DTI depletion regions 1260 may be similar to DTI depletion regions 1060 and 1160 shown in FIGS. 10 and 11, respectively. Conductor 1210 may be similar to conductors 1010 and 1110 shown in FIGS. 10 and 11, respectively.

Spacing 1262, length 1264, width 1266, and depth 1268 of DTI depletion regions 1260 may be varied to improve the quality factor of inductor 1250. The optimization may be based on the intended application of inductor 1250. Additionally, spacing 1262 of DTI depletion regions 1260 may be designed such that the depletion regions created by DTI depletion regions 1260 do not merge.

Additionally, or alternatively, width 1212, length 1214, and depth 1216 of conductor 1210 may be varied to improve the quality factor of inductor 1250. The optimization may be based on the intended application of inductor 1250. For example, depth 1268 of DTI depletion regions 1260 or depth 1216 of conductor 1210 may be adjusted such that DTI depletion regions 1260 are created where eddy currents from inductor 1250 are present. Spacing 1262, length 1264, width 1266, and depth 1268 of DTI depletion regions 1260 may be improved by tuning with simulation models. Additionally, or alternatively, width 1212, length 1214, and depth 1216 of conductor 1210 may be improved by tuning with simulation models. For example, spacing 1262, length 1264, width 1266, and depth 1268 of DTI depletion regions 1260 may be improved to increase the quality factor of inductor 1250 for a given application.

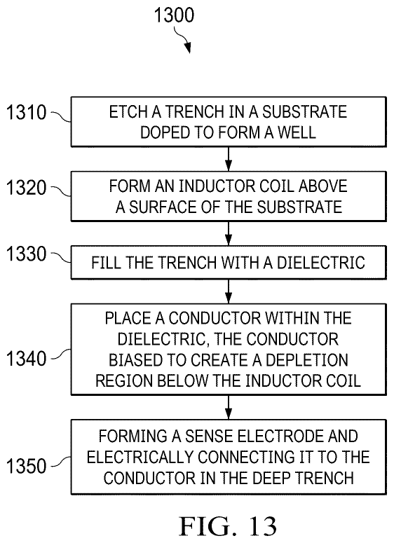

FIG. 13 illustrates a method performed for manufacturing an ion sensing device having an inductor with depletion regions created using DTI, according to examples of the present disclosure. Method 1300 may be implemented using any suitable semiconductor manufacturing device designed to perform the functions disclosed herein or any other system operable to implement method 1300. Although examples have been described above, other variations and examples may be made from this disclosure without departing from the spirit and scope of these disclosed examples.

Method 1300 may begin at block 1310 where a trench may be etched in a substrate doped to form a well. The substrate may form either a P-well or an N-well. The substrate may be any suitable substrate, such as a silicon, silicon on insulator (SOI), gallium arsenide (GaAs), gallium nitride (GaN), silicon carbide (SiC), germanium, indium phosphide (InP), sapphire, or any combination thereof. In some examples, the substrate may be layered on an insulator layered on a silicon base. The trench may have a depth on the order of tens of micro-meters. The trench may be etched using any suitable technique, such as DRIE.

At block 1320, an inductor coil may be formed above a surface of the substrate. The inductor coil may be formed of layered metal stacks arranged in a coil shape.

At block 1330, the trench may be filled with a dielectric. The dielectric may be formed of any suitable insulating material, such as an oxide (e.g., silicon dioxide) or a nitride (e.g., silicon nitride). The dielectric may be filled in the trench using any suitable technique, such as CVD or PECVD.

At block 1340, a conductor may be placed with in the dielectric in the trench. The conductor may be formed of any suitable conductive material, such as polysilicon or metal (e.g., aluminum or copper). The conductor may be filled in the dielectric in the trench using any suitable technique, such as CVD or PECVD. The conductor in the trench may be biased to create a depletion region below the inductor coil.

A sense electrode may be formed 1350 and electrically connected to the depletion region.

Although FIG. 13 discloses a particular number of operations related to method 1300, method 1300 may be executed with greater or fewer operations than those depicted in FIG. 13. In addition, although FIG. 13 discloses a certain order of operations to be taken with respect to method 1300, the operations comprising method 1300 may be completed in any suitable order.

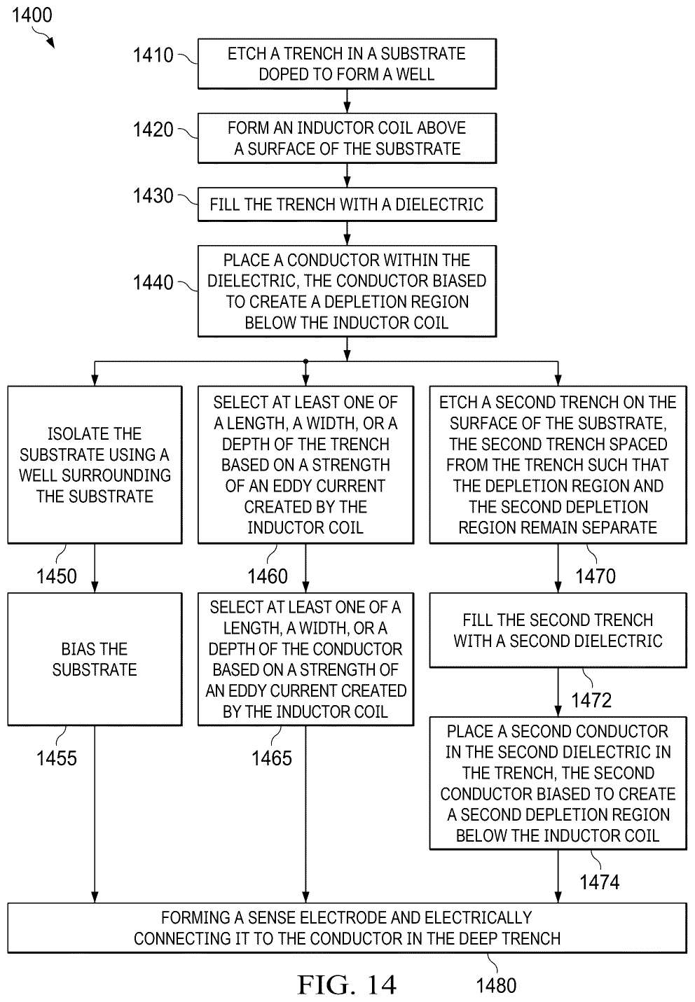

FIG. 14 illustrates a more detailed method performed for manufacturing an ion sensing device having an inductor with depletion regions created using DTI, according to examples of the present disclosure. Method 1400 may be implemented using any suitable semiconductor manufacturing device designed to perform the functions disclosed herein or any other system operable to implement method 1400. Although examples have been described above, other variations and examples may be made from this disclosure without departing from the spirit and scope of these disclosed examples.

Method 1400 may begin at block 1410 where a trench may be etched in a substrate doped to form a well. The substrate may form either a P-well or an N-well. The substrate may be any suitable substrate, such as a silicon, silicon on insulator (SOI), gallium arsenide (GaAs), gallium nitride (GaN), silicon carbide (SiC), germanium, indium phosphide (InP), sapphire, or any combination thereof. In some examples, the substrate may be layered on an insulator layered on a silicon base. The trench may have a depth on the order of tens of micro-meters. The trench may be etched using any suitable technique, such as DRIE.

At block 1420, an inductor coil may be formed above a surface of the substrate. The inductor coil may be formed of layered metal stacks arranged in a coil shape.

At block 1430, the trench may be filled with a dielectric. The dielectric may be formed of any suitable insulating material, such as an oxide (e.g., silicon dioxide) or a nitride (e.g., silicon nitride). The dielectric may be filled in the trench using any suitable technique, such as CVD or PECVD.

At block 1440, a conductor may be placed with in the dielectric in the trench. The conductor may be formed of any suitable conductive material, such as polysilicon or metal (e.g., aluminum or copper). The conductor may be filled in the dielectric in the trench using any suitable technique, such as CVD or PECVD. The conductor in the trench may be biased to create a depletion region below the inductor coil.

At block 1450, the substrate may be isolated using a well surrounding the substrate. The substrate may be isolated to allow for biasing of the well (either P-well or N-well) formed by the substrate. The substrate may be isolated by surrounding the substrate with wells and a buried layer. Wells and the buried layer may have an opposite bias as the substrate. Specifically, where the substrate is a P-well, the well may be an N-well and the buried layer may be an N-buried layer. Likewise, where the substrate is a N-well, the well may be a P-well and the buried layer may be a P-buried layer.

At block 1455, the substrate may be biased. The substrate may be a P-well or an N-well.

At block 1460, at least one of a length, a width, or a depth of the trench may be selected based on an eddy current created by the inductor coil. At block 1465, at least one of a length, a width, or a depth of the conductor may be selected based on an eddy current created by the inductor coil. The selection may be based on the intended application of the inductor coil. The selection may also be based on optimizing the quality factor of the inductor coil.

At block 1470, a second trench may be etched in a substrate doped to form a well. The substrate may form either a P-well or an N-well. The substrate may be any suitable substrate, such as a silicon, silicon on insulator (SOI), gallium arsenide (GaAs), gallium nitride (GaN), silicon carbide (SiC), germanium, indium phosphide (InP), sapphire, or any combination thereof. In some examples, the substrate may be layered on an insulator layered on a silicon base. The second trench may have a depth on the order of tens of micro-meters. The second trench may be etched using any suitable technique, such as DRIE. The second trench may be substantially parallel to the trench. The second trench may be spaced from the trench such that the depletion region and a second depletion region created by the second trench remain separate. The spacing between the trench and the second trench may be based on a strength of an eddy current created by the inductor coil.

At block 1472, the second trench may be filled with a second dielectric. The second dielectric may be formed of any suitable insulating material, such as an oxide (e.g., silicon dioxide) or a nitride (e.g., silicon nitride). The second dielectric may be filled in the second trench using any suitable technique, such as CVD or PECVD.

At block 1474, a second conductor may be placed with in the second dielectric in the second trench. The second conductor may be formed of any suitable conductive material, such as polysilicon or metal (e.g., aluminum or copper). The second conductor may be filled in the second dielectric in the second trench using any suitable technique, such as CVD or PECVD. The second conductor in the second trench may be biased to create a second depletion region below the inductor coil.

A sense electrode may be formed 1480 and electrically connected to the depletion region.

Although FIG. 14 discloses a particular number of operations related to method 1400, method 1400 may be executed with greater or fewer operations than those depicted in FIG. 14. In addition, although FIG. 14 discloses a certain order of operations to be taken with respect to method 1400, the operations comprising method 1400 may be completed in any suitable order.

Although examples have been described above, other variations and examples may be made from this disclosure without departing from the spirit and scope of these disclosed examples.

What is claimed is:

1. A device, comprising:
a substrate doped to form a first well;
a first deep trench etched in the substrate;
a dielectric in the first deep trench;
a first conductor within the dielectric in the first deep trench and biased to create a first depletion region in the substrate proximate the first deep trench, wherein the first conductor and first depletion region form a first deep trench isolation varactor;
a sense electrode operable to become electrically charged when interacting with an ionized fluid, wherein the sense electrode is operable to electrically charge the first deep trench isolation varactor;
an inductor proximate the first deep trench isolation varactor and configured so that a change of a characteristic of the first deep trench isolation varactor induces a change in the quality factor of the inductor; and
a fluid property measurement circuit operable to determine a change in the quality factor of the inductor and output a fluid property signal.

2. The device of claim 1, comprising a sensing membrane connected to the sense electrode and operable to electrically communicate with the sense electrode, wherein the sensing membrane is sensitive to any ion type or a specific ion type in the ionized fluid.

3. The device of claim 1, comprising:
a second well surrounding the substrate and operable to isolate the substrate; and
a buried layer proximate the substrate and operable to isolate the substrate, whereby the isolated substrate is biased.

4. The device of claim 1, wherein at least one of a length, a width, or a depth of the trench or at least one of a length, a width, or a depth of the conductor is selected based on a strength of an eddy current induced by the inductor.

5. The device of claim 1, comprising:
a second deep trench etched in the substrate;
a dielectric in the second deep trench; and
a second conductor within the dielectric in the second deep trench and biased to create a second depletion region in the substrate proximate the second deep trench, wherein the second conductor and second depletion region form a second deep trench isolation varactor,
wherein the sense electrode is operable to electrically charge the second deep charge isolation varactor,
wherein the first and second deep trenches are spaced apart so that the first and second depletion regions are separate.

6. The device of claim 5, wherein the second deep trench isolation varactor is electrically insulated from the ionized fluid, whereby the second deep trench isolation varactor is a reference varactor, wherein a reference inductor is proximate the reference varactor.

7. The device of claim 5, wherein the spacing between the first deep trench and the second deep trench is based on a strength of an eddy current induced by the inductor.

8. The device of claim 1, further comprising:
a silicon base; and
an insulator on the silicon base, wherein the substrate is on the insulator.

9. The device of claim 1, comprising: a control gate operable to reset or calibrate an electrical communication between the sense electrode and the first deep trench isolation varactor.

10. A method, comprising:
sensing an ionized fluid via a sense electrode;
charging a first deep trench isolation varactor via the sense electrode based on the sensing an ionized fluid, wherein the first deep trench isolation varactor comprises a conductor in a dielectric in a deep trench in a substrate, the conductor biased to create a depletion region in the substrate proximate the deep trench;
inducing a change in a quality factor of an inductor via charging the first deep trench isolation varactor;
measuring a quality factor of the inductor; and
outputting a fluid property signal corresponding to the measured quality factor of the inductor.

11. The method of claim 10, wherein sensing an ionized fluid via a sense electrode comprises sensing any ion type or a specific ion type.

12. The method of claim 10, comprising:
measuring a quality factor of a reference inductor; and
comparing the measured quality factor of the inductor with the measured quality factor of the reference inductor.

13. The method of claim 10, comprising resetting or calibrating the quality factor of the inductor via a control gate.

14. The method of claim 10, comprising isolating the first deep trench isolation varactor to form an isolated well and biasing the isolated well to create a depletion region in the isolated substrate proximate the deep trench.

15. A fluid property sensor made by a process comprising:
etching a first deep trench in a substrate, the substrate doped to form a well;
filling the first deep trench with a dielectric;
placing a first conductor within the dielectric, the conductor biased to create a first depletion region proximate the first deep trench, wherein the first conductor and the first depletion region form a first deep trench isolation varactor;
connecting a sense electrode to the first deep trench isolation varactor, wherein the sense electrode is operable to be electrically charged when interacting with an ionized fluid, wherein the sense electrode is operable to electrically charge the first deep trench isolation varactor;
positioning an inductor proximate the first deep trench isolation varactor, wherein the inductor has a quality factor; and
providing a fluid property measurement circuit operable to determine a change in the quality factor of the inductor and output a fluid property signal.

16. The fluid property sensor made by the process of claim 15, the process comprising:
isolating the substrate using a second well surrounding the substrate; and
biasing the isolated substrate.

17. The fluid property sensor made by the process of claim 15, wherein at least one of a length, a width, or a depth of the trench or at least one of a length, a width, or a depth of the conductor is selected based on a strength of an eddy current created by the inductor coil.

18. The fluid property sensor made by the process of claim 15, the process comprising:
etching a second deep trench in the substrate;
filling the second deep trench with a dielectric; and
placing a second conductor in the dielectric in the second deep trench, the second conductor biased to create a second depletion region, wherein a spacing between the first deep trench and the second deep trench is such that the first depletion region and the second depletion region remain separate.

19. The fluid property sensor made by the process of claim 15, comprising forming a reference varactor in the substrate and positioning a reference inductor proximate the reference varactor electrically insulated from the ionized fluid.

20. The fluid property sensor made by the process of claim 15, comprising forming a control gate operable to reset or calibrate the first deep trench isolation varactor.
